(19) United States
(12) Patent Application Publication
(10) Pub. No.: US 2010/0302385 A1
(43) Pub. Date: Dec. 2, 2010

(54) ANGULAR VELOCITY SENSOR, AMPLIFICATION CIRCUIT OF ANGULAR VELOCITY SIGNAL, ELECTRONIC APPARATUS, SHAKE CORRECTION APPARATUS, AMPLIFICATION METHOD OF ANGULAR VELOCITY SIGNAL, AND SHAKE CORRECTION METHOD

(75) Inventor: Kazuo KURIHARA, Miyagi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Sony Corporation, Tokyo (JP)

(21) Appl. No.: 12/767,175

(22) Filed: Apr. 26, 2010

(30) Foreign Application Priority Data
May 29, 2009 (JP) 2009-130137
Jan. 14, 2010 (JP) 2010-005632

(51) Int. Cl. H04N 5/228; G01C 19/56; H03F 3/45; H05K 7/00

(52) U.S. Cl. 348/208.4; 73/504.12; 330/69; 361/807; 348/E05.031

(57) ABSTRACT

An angular velocity sensor includes a sensor device and an amplification circuit. The sensor device generates a detection signal corresponding to an angular velocity. The amplification circuit generates both a first output signal by non-inverting amplifying the detection signal with a first gain and a second output signal by inverting-amplifying the detection signal with the first gain, and outputs the first output signal and the second output signal in order to obtain an angular velocity signal by calculating a difference between the first output signal and the second output signal.

### BACKGROUND OF THE INVENTION

1. Field of the Invention

The invention relates to an angular velocity sensor, an amplification circuit of an angular velocity signal, an electronic apparatus, a shake correction apparatus, an amplification method of an angular velocity signal and a shake correction method, which are used for detecting a shake of a digital still camera, a digital video camera and the like and correcting the shake thereof.

2. Description of the Related Art

Recently, there has been developed a digital still camera, a digital video camera and the like which is provided with a shake correction mechanism that corrects blurring of a photographed image caused by a so-called shake. As this kind of a shake correction mechanism, for example, there has been known a mechanism (refer to Japanese Unexamined Patent Application Publication No. 1992-95933) that performs image blurring correction by allowing an optical axis of an optical system for image formation to be eccentric, and a mechanism (refer to Japanese Unexamined Patent Application Publication No. 1991-145880) that corrects a shake through image processing. Further, Japanese Unexamined Patent Application Publication No. 1992-211230 discloses a shake correction apparatus including an angular velocity sensor, a mirror that introduces an object image to a photographing lens, and a bimorph that tilts the mirror based on output of the angular velocity sensor in such a manner that the fluctuation of an image due to a deflection angle of a camera is allowed to be offset.

In general, a shake correction mechanism detects rotation movement of a camera caused by a shake by using a sensor, and amplifies an angular velocity signal included in a detection signal of the sensor to obtain angle information. Since the signal from the sensor is very small and includes drift components, it is usual that DC components are removed by passing through a high pass filter during amplification (for example, refer to paragraphs [0002] and [0003] of Japanese Unexamined Patent Application Publication No. 1998-65956).

### SUMMARY OF THE INVENTION

In recent years, with the low power consumption of an electronic apparatus, voltage of driving circuits of various mechanism units is lowered. In relation to a shake correction mechanism, a voltage range of an output signal from an angular velocity sensor may not be increased, resulting in the difficulty in ensuring a dynamic range. Therefore, when a relatively high angular velocity is detected, an angular velocity detection range may be exceeded, so that shake correction may not be appropriately performed. Meanwhile, since shake detection sensitivity should be reduced in order to ensure an angular velocity detection range, ensuring of necessary resolution may be difficult and shake correction may not be performed with high accuracy.

In view of the above issues, it is desirable to provide an angular velocity sensor, an amplification circuit of an angular velocity signal, an electronic apparatus, a shake correction apparatus, an amplification method of an angular velocity signal and a shake correction method, which can increase a dynamic range without reduction in sensitivity.

According to one embodiment of the invention, there is provided an angular velocity sensor including a sensor device and an amplification circuit.

The sensor device generates a detection signal corresponding to an angular velocity.

The amplification circuit generates both a first output signal by non-inverting amplifying the detection signal with a first gain and a second output signal by inverting-amplifying the detection signal with the first gain, and outputs the first output signal and the second output signal in order to obtain an angular velocity signal by calculating a difference between the first output signal and the second output signal.

The first and second output signals output from the amplification circuit are amplified with the same gain and have polarities different from each other. That is, the first output signal is in a differential relationship with the second output signal. The angular velocity signal is obtained by calculating the difference between the two output signals with the differential relationship. Consequently, the angular velocity signal having a detection range of two times the existing detection range can be generated. Further, if the first gain is set to ½ of the total gain of the amplification circuit, an angular velocity detection range of two times the existing detection range can be ensured while maintaining the output sensitivity of an angular velocity, as compared with the case in which the detection signal is amplified with the total gain by an amplification circuit of a single stage.

The angular velocity sensor may further include a switch circuit that selectively switches a first state in which the first output signal is output from the amplification circuit, and a second state in which the second output signal is output from the amplification circuit.

With such a configuration, the amplification circuit can output the first output signal and the second output signal in time-series, resulting in the reduction of the number of output terminals of the amplification circuit.

In the angular velocity sensor, the amplification circuit may include a first amplification circuit section and a second amplification circuit section.

The first amplification circuit section generates the first output signal by non-inverting amplifying the detection signal with the first gain and outputs the first output signal.

The second amplification circuit section generates a third output signal by inverting-amplifying the detection signal with a second gain with a value of 1, and inputs the third output signal to the first amplification circuit section so that the second output signal is output from the first amplification circuit section.

In such a case, the switch circuit includes a first switch circuit section capable of limiting input of the detection signal to the first amplification circuit section, and a second switch circuit section capable of limiting input of the third output signal to the first amplification circuit section.

With such a configuration, the first and second switch circuit sections are switched, so that the first output signal and the second output signal can be output from the first amplification circuit section in time-series. The angular velocity signal is generated based on the first and second output signals.

When the amplification circuit includes a first amplification circuit section and a second amplification circuit section, the first amplification circuit section may generate the second output signal by inverting-amplifying the detection signal with the first gain and output the second output signal. In such a case, the second amplification circuit section generates a third output signal by inverting-amplifying the detection signal with a second gain with a value of 1, and inputs the third output signal to the first amplification circuit section so that the first output signal is output from the first amplification circuit section.

In such a case, the switch circuit includes a first switch circuit section capable of limiting input of the detection signal to the first amplification circuit section, and a second switch circuit section capable of limiting input of the third output signal to the first amplification circuit section.

Even in such a case, the first and second switch circuit sections are switched, so that the first output signal and the second output signal can be output from the first amplification circuit section in time-series.

In the angular velocity sensor, the sensor device may include a first sensor device section and a second sensor device section.

The first sensor device section generates a first detection signal corresponding to an angular velocity about a first axis along a first direction as the detection signal.

The second sensor device section generates a second detection signal corresponding to an angular velocity about a second axis along a second direction different from the first direction as the detection signal.

In such a case, the first state is classified into a first switching state in which the first output signal related to the first detection signal is output from the amplification circuit, and a second switching state in which the first output signal related to the second detection signal is output from the amplification circuit.

Meanwhile, the second state is classified into a third switching state in which the second output signal related to the first detection signal is output from the amplification circuit, and a fourth switching state in which the second output signal related to the second detection signal is output from the amplification circuit.

With such a configuration, a common amplification circuit can be provided in each sensor device section, resulting in the contribution to the miniaturization of the amplification circuit and the reduction of the number of parts.

When a sensor device includes the two device sections, the second amplification circuit section can be formed with a first inverting amplifier and a second inverting amplifier. The first inverting amplifier generates a fourth output signal as the third output signal by inverting-amplifying the first detection signal with the second gain. The second inverting amplifier generates a fifth output signal as the third output signal by inverting-amplifying the second detection signal with the second gain.

At this time, the first switch circuit section includes a first switch portion capable of limiting input of the first detection signal to the first amplification circuit section, and a second switch portion capable of limiting input of the second detection signal to the first amplification circuit section. The second switch circuit section includes a third switch portion capable of limiting input of the fourth detection signal to the first amplification circuit section, and a fourth switch portion capable of limiting input of the fifth detection signal to the first amplification circuit section.

With such a configuration, the first and second output signals related to the first detection signal and the first and second output signals related to the second detection signal can be output from the amplification circuit in time-series. Angular velocity signals about the first and second axes can be generated based on the first and second output signals output from the amplification circuit.

Meanwhile, when a sensor device includes the two device sections, the second amplification circuit section can be formed with an inverting amplifier of a single stage. That is, the second amplification circuit section generates the third output signal by inverting-amplifying the first detection signal with the second gain when the first detection signal is received, and generates the third output signal by inverting-amplifying the second detection signal with the second gain when the second detection signal is received.

At this time, the first switch circuit section includes a fifth switch portion and a sixth switch portion as well as a first switch portion and a second switch portion. The fifth switch portion is configured to limit input of the first detection signal to the second amplification circuit section, and the sixth switch portion is configured to limit input of the second detection signal to the second amplification circuit section.

With such a configuration, the first and second output signals related to the first detection signal and the first and second output signals related to the second detection signal can be output from the amplification circuit in time-series.

In the angular velocity sensor, the first to fourth switching states may be sequentially switched by the switch circuit in a predetermined order. In such a case, a switch frequency of each switching state is set to be equal to or more than 400 Hz.

With such a configuration, for example, it is possible to effectively generate an angular velocity signal necessary for shake correction control and the like by using a common amplification circuit provided in each sensor device section.

The angular velocity sensor may further include a high pass filter provided between the first amplification circuit section and the second amplification circuit section to remove drift components from the detection signal.

With such a configuration, it is possible to effectively remove drift components of a detection signal which may cause adverse effects when angular velocity detection is performed with high accuracy.

In the angular velocity sensor, the high pass filter includes a capacitor and a resistor. The capacitor has a first electrode connected to an input side of the first amplification circuit section and a second electrode connected to an output side of the second amplification circuit section. The resistor is connected between the first electrode and a reference potential. In such a case, the angular velocity sensor may further include a switch mechanism that bypasses the resistor to achieve a connection between the first electrode and the reference potential when the first switch circuit section limits the input of the detection signal to the first amplification circuit section.

With such a configuration, the first electrode can be charged and discharged for a time shorter than a time constant decided by the product of the capacitor and the resistor. Consequently, an angular velocity signal can be generated with high accuracy.

In the angular velocity sensor, when the amplification circuit includes a first amplification circuit section and a second amplification circuit section, the first and second amplification circuit sections may have the following configuration.

That is, the first amplification circuit section generates the first output signal by non-inverting amplifying the detection signal with the first gain and outputs the first output signal.

In such a case, the second amplification circuit section generates the second output signal by inverting-amplifying the first output signal with a second gain with a value of 1, and outputs the second output signal.

With such a configuration, the first and second output signals can be input to a signal processing circuit at the same time.

Alternatively, a first amplification circuit section may generate the second output signal by inverting-amplifying the detection signal with the first gain and output the second output signal.

In such a case, a second amplification circuit section may generate the first output signal by inverting-amplifying the second output signal with a second gain with a value of 1, and output the first output signal.

Even in such a case, the first and second output signals can be input to a signal processing circuit at the same time.

The angular velocity sensor may further include a high pass filter provided at a front stage of the first amplification circuit section to remove drift components from the detection signal.

The angular velocity sensor may further include a gain variable circuit capable of variably setting the first gain.

With such a configuration, an optimization value of a different gain can be easily set using a common amplification circuit according to the processing capacity and purpose of a signal processing circuit that calculates the difference between the first output signal and the second output signal to generate an angular velocity signal.

According to another embodiment of the invention, there is provided an amplification circuit of an angular velocity signal, including an amplification circuit section that generates both a first output signal by non-inverting amplifying a detection signal corresponding to an angular velocity with a first gain and a second output signal by inverting-amplifying the detection signal with the first gain, and outputs the first output signal and the second output signal in order to obtain an angular velocity signal by calculating a difference between the first output signal and the second output signal.

According to further another embodiment of the invention, there is provided an electronic apparatus including a casing, a sensor device, an amplification circuit and a signal processing circuit.

The sensor device generates a detection signal corresponding to an angular velocity acting on the casing.

The amplification circuit generates both a first output signal by non-inverting amplifying the detection signal with a first gain and a second output signal by inverting-amplifying the detection signal with the first gain, and outputs the first output signal and the second output signal.

The signal processing circuit calculates a difference between the first output signal and the second output signal to generate an angular velocity signal.

The first and second output signals output from the amplification circuit are amplified with the same gain and have polarities different from each other. That is, the first output signal is in a differential relationship with the second output signal. Thus, the signal processing circuit calculates the difference between the two output signals to generate the angular velocity signal having a detection range of two times the existing detection range. Further, if the first gain is set to ½ of the total gain of the amplification circuit, an angular velocity detection range of two times the existing detection range can be ensured while maintaining the output sensitivity of an angular velocity, as compared with the case in which the detection signal is amplified with the total gain by an amplification circuit of a single stage.

The electronic apparatus may further include an image capturing unit and a correction mechanism.

The image capturing unit is received in the casing to capture an object image.

The correction mechanism corrects a shake of the object image based on the angular velocity signal generated by the signal processing circuit.

With such a configuration, shake correction can be performed with high accuracy based on the generated angular velocity signal.

According to still another embodiment of the invention, there is provided a shake correction apparatus including an image capturing unit, a sensor device, an amplification circuit, a signal processing circuit and a correction mechanism.

The image capturing unit captures an object image.

The sensor device generates a detection signal corresponding to an angular velocity.

The amplification circuit generates both a first output signal by non-inverting amplifying the detection signal with a first gain and a second output signal by inverting-amplifying the detection signal with the first gain, and outputs the first output signal and the second output signal.

The signal processing circuit calculates a difference between the first output signal and the second output signal to generate an angular velocity signal.

The correction mechanism corrects a shake of the object image based on the angular velocity signal generated by the signal processing circuit.

In an amplification method of an angular velocity signal according to yet another embodiment of the invention, a detection signal corresponding to an angular velocity is generated. Next, a first output signal is generated by non-inverting amplifying the detection signal with a first gain and a second output signal is generated by inverting-amplifying the detection signal with the first gain.

Then, the first output signal and the second output signal are output in order to obtain an angular velocity signal by calculating a difference between the first output signal and the second output signal.

In a shake correction method according to yet another embodiment of the invention, a detection signal corresponding to an angular velocity is generated. Next, a first output signal is generated by non-inverting amplifying the detection signal with a first gain and a second output signal is generated by inverting-amplifying the detection signal with the first gain. Then, the first output signal and the second output signal are output. Thereafter, a difference between the first output signal and the second output signal is calculated to generate an angular velocity signal. Last, a shake of an object image is corrected based on the generated angular velocity signal.

According to an embodiment of the invention as described above, an angular velocity signal with a wide angular velocity detection range can be generated. Consequently, for example, shake correction can be performed with high accuracy.

### BRIEF DESCRIPTION OF THE DRAWINGS

FIG. 1 is a perspective view illustrating an electronic apparatus according to one embodiment of the invention;

FIG. 2 is a block diagram illustrating the configuration of a shake correction mechanism in an electronic apparatus;

FIG. 3 is a circuit diagram illustrating the configuration of a basic amplification circuit of an angular velocity signal;

FIG. 4 is a schematic diagram illustrating an output dynamic range of an amplification circuit shown in FIG. 3;

FIGS. 5A and 5B are schematic diagrams illustrating one example of variation of an output voltage of an amplification circuit shown in FIG. 3 with respect to time;

FIG. 6 is a circuit diagram illustrating the configuration of an amplification circuit of an angular velocity signal according to a first embodiment of the invention;

FIGS. 7A and 7B are schematic diagrams illustrating variation of an output voltage of an amplification circuit shown in FIG. 6 with respect to time, FIG. 7A is a schematic diagram illustrating one example of variation of first and second output signals (output voltages) with respect to time, and FIG. 7B is a schematic diagram illustrating variation of a differential signal of first and second output signals with respect to time;

FIG. 8 is a circuit diagram illustrating the configuration of an amplification circuit of an angular velocity signal according to a second embodiment of the invention;

FIG. 9 is a circuit diagram illustrating the configuration of an amplification circuit of an angular velocity signal according to a third embodiment of the invention;

FIG. 10 is a timing chart illustrating the relationship between state variation of switch sections in an amplification circuit shown in FIG. 9 and an output signal of the amplification circuit;

FIG. 11 is a circuit diagram illustrating the configuration of an amplification circuit of an angular velocity signal according to a fourth embodiment of the invention;

FIG. 12 is a timing chart illustrating the relationship between state variation of switch sections in an amplification circuit shown in FIG. 11 and an output signal of the amplification circuit;

FIG. 13 is a circuit diagram illustrating the configuration of an amplification circuit of an angular velocity signal according to a fifth embodiment of the invention;

FIGS. 14A to 14C are circuit diagrams illustrating main elements according to modified examples of the configuration of an amplification circuit shown in FIG. 13;

FIG. 15 is a circuit diagram illustrating the configuration of an amplification circuit of an angular velocity signal according to a sixth embodiment of the invention;

FIG. 16 is a table illustrating the relationship between each switch section in an amplification circuit shown in FIG. 15 and an output signal;

FIG. 17 is a timing chart illustrating the relationship between state variation of each switch section in an amplification circuit shown in FIG. 15 and an output signal of the amplification circuit;

FIG. 18 is a circuit diagram illustrating the configuration of an amplification circuit of an angular velocity signal according to a seventh embodiment of the invention;

FIG. 19 is a circuit diagram illustrating the configuration of an amplification circuit of an angular velocity signal according to an eighth embodiment of the invention;

FIG. 20 is a table illustrating the relationship between each switch section in an amplification circuit shown in FIG. 19 and an output signal;

FIG. 21 is a timing chart illustrating the relationship between state variation of each switch section in an amplification circuit shown in FIG. 19 and an output signal of the amplification circuit;

FIG. 22 is a block diagram illustrating the configuration of a controller (FIG. 2) including a signal processing circuit;

FIG. 23 is a circuit diagram illustrating one example in which an amplification circuit includes the combination of an inverting amplifier and another inverting amplifier;

FIG. 24 is a circuit diagram illustrating one example in which an amplification circuit includes the combination of an inverting amplifier and another inverting amplifier;

FIG. 25 is a circuit diagram illustrating one example in which an amplification circuit includes the combination of an inverting amplifier and another inverting amplifier;

FIG. 26 is a circuit diagram illustrating one example in which an amplification circuit includes the combination of an inverting amplifier and another inverting amplifier; and

FIG. 27 is a circuit diagram illustrating one example in which an amplification circuit includes the combination of an inverting amplifier and another inverting amplifier.

### DESCRIPTION OF THE PREFERRED EMBODIMENTS

Hereinafter, preferred embodiments of the invention will be described with reference to the accompanying drawings.

### First Embodiment

[Electronic Apparatus]

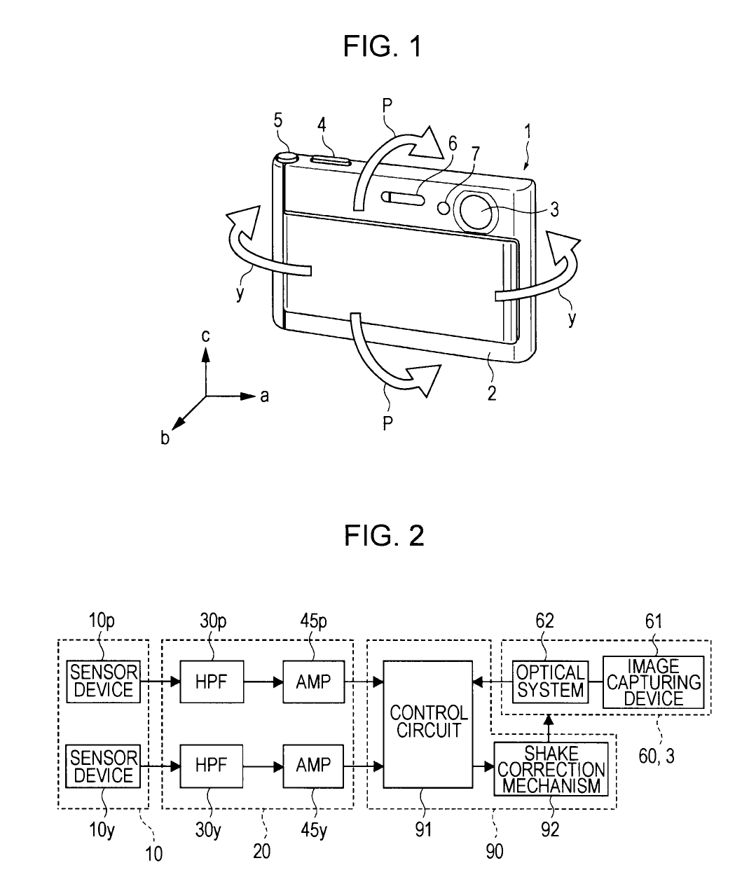

FIG. 1 is a perspective view illustrating an electronic apparatus according to one embodiment of the invention. In the invention, a digital still camera (hereinafter, simply referred to as “camera”) will be described as an example of the electronic apparatus.

The camera 1 of the embodiment includes a casing 2. The casing 2 is provided therein with an image capturing unit 3 for capturing an object image, a shutter button 4, a function switch 5 for setting various camera functions, a strobe light emitting unit 6, a distance measuring sensor 7 for auto-focus control, and the like. Although not shown in FIG. 1, the casing 2 is provided at a rear side thereof with a display unit including a liquid crystal device, an organic EL (electroluminescence) device and the like to display the object image imaged by the image capturing unit 3.

The camera 1 includes a shake correction mechanism. The shake correction mechanism is provided in the casing 2 to prevent blurring of the object image due to a shake of the camera 1. In more detail, the shake correction mechanism includes a detecting section for detecting an angular velocity acting in a predetermined direction corresponding to the casing 2, a signal processing circuit for generating a correction signal based on the detected angular velocity, and a correction mechanism for correcting a shake based on the correction signal. The correction mechanism corrects the shake using various schemes such as a scheme for electronically correcting image data or a scheme for mechanically adjusting an optical axis in the direction of cancelling a shake. According to the latter scheme, any one of an optical lens and a solid-state imaging device, which constitute the image capturing unit 3, is allowed to be moved, thereby adjusting the position of an axis of light incident on the solid-state imaging device.

The detection direction of the angular velocity acting on the casing 2 is typically detected in two directions of FIG. 1, that is, a yaw direction indicated by a “y” and a pitch direction indicated by a “p” with respect to the casing 2. Herein, the yaw direction denotes a rotation direction of an axis parallel to a height direction (c axis direction) of the casing 2, and the pitch direction denotes a rotation direction of an axis parallel to a width direction (a axis direction) of the casing 2. Thus, it is possible to correct a shake occurring when the direction of the casing 2 is changed to the yaw direction and the pitch direction. In addition to this, it may be possible to detect an angular velocity with respect to a roll direction of rotation of an axis parallel to a thickness direction (b axis direction) of the casing 2 and to correct a shake regarding the direction.

[Shake Correction Apparatus]

FIG. 2 is a block diagram illustrating the configuration of the shake correction mechanism. The shake correction mechanism shown in FIG. 2 includes a detector 10, an amplification circuit 20 and a controller 90.

The detector 10 includes two sensor devices for detecting angular velocities of the yaw direction and the pitch direction. That is, the detector 10 includes a sensor device 10y for detecting the angular velocity of the yaw direction and a sensor device 10p for detecting the angular velocity of the pitch direction. These sensor devices 10y and 10p include a device for generating detection signals corresponding to the angular velocities. In the embodiment, these sensor devices 10y and 10p include a piezoelectric vibration type gyro sensor for detecting Coriolis force which is proportional to the angular velocities. The sensor devices 10y and 10p have the same reference potential and output potential signals, which are proportional to the magnitude of the angular velocities, as variation of a potential with respect to the reference potential. The reference potential may be set to a predetermined offset potential (DC potential) or a ground potential.

The amplification circuit 20 amplifies the detection signals input from the detector 10 with a predetermined amplification factor (gain), and outputs the amplified detection signals to the controller 90. The amplification circuit 20 includes high pass filters 30y and 30p and amplification circuit sections 45y and 45p. The high pass filter 30y removes drift components included in the detection signal from the sensor devices 10y, and the high pass filter 30p removes drift components included in the detection signal from the sensor devices 10p. The amplification circuit section 45y amplifies the detection signal, which has passed through the high pass filter 30y, with a predetermined gain, and the amplification circuit section 45p amplifies the detection signal, which has passed through the high pass filter 30p, with the predetermined gain.

The controller 90 includes a control circuit 91 and a shake correction mechanism 92. The control circuit 91 generates angular velocity signals of the yaw direction and the pitch direction from the detection signals of the yaw direction and the pitch direction, which have been amplified by the amplification circuit 20. Further, the control circuit 91 generates a correction signal for driving the shake correction mechanism 92 based on the generated angular velocity signals. The shake correction mechanism 92 drives an image capturing unit 60 (corresponding to the image capturing unit 3 of FIG. 1) including an image capturing device 61 and an optical system 62 based on the correction signal, and adjusts an optical axis of an object image incident on the image capturing device 61. The optical axis adjustment can be performed using various schemes, for example, by shifting an optical lens, which is a part of the optical system 62, or an image capturing device 63 in the direction of cancelling a shake. Various solid-state imaging devices, such as CODs (Charge Coupled Devices) or CMOSs (Complementary Metal-Oxide Semiconductors), can be applied to the image capturing device 63.

A scheme by which the image capturing unit 60 is driven by the shake correction mechanism 92 is not particularly limited. Further, the scheme is not limited to the above example. For example, an electronic shake correction method using an image processing circuit may be employed. Furthermore, the image capturing unit 60 may be configured to input difference information regarding positions before and after the adjustment by the shake correction mechanism 92 to the control circuit 91. In this way, a feedback control system for shake correction is constructed, so that shake correction can be implemented with high accuracy.

[Angular Velocity Sensor]

The sensor devices 10y and 10p constituting the detector 10 are mounted on a common circuit board (primary board) together with a self-excited oscillation circuit for piezoelectrically driving these sensor devices, the amplification circuit 20 for amplifying the detection signals from the sensor devices 10y and 10p, a signal processing circuit for generating an angular velocity signal from an output signal of the amplification circuit 20 and the like, thereby constituting one sensor part (angular velocity sensor). The angular velocity sensor constituted in this way is mounted on a control board (secondary board) of the camera 1, thereby constituting the shake correction apparatus. In addition, the high pass filters 30y and 30p constituting the amplification circuit 20 may be mounted at a side of the control board (secondary board).

The self-excited oscillation circuit, the amplification circuit and the signal processing circuit may be independently mounted on the primary board. Alternatively, these circuits may be configured to be mounted on a support board after being integrated on a single semiconductor chip. In the embodiment, if not otherwise specified, a case in which an amplification circuit which will be described later is one element of the angular velocity sensor will be described as an example. The correction signal for driving the shake correction mechanism 92 is generated in a control unit mounted on the secondary board, other than the angular velocity sensor. In such a case, the control circuit 91 includes the control unit and the signal processing circuit in the angular velocity sensor.

Next, the amplification circuit 20 will be described in detail.

[Amplification Circuit of Angular Velocity Signal]

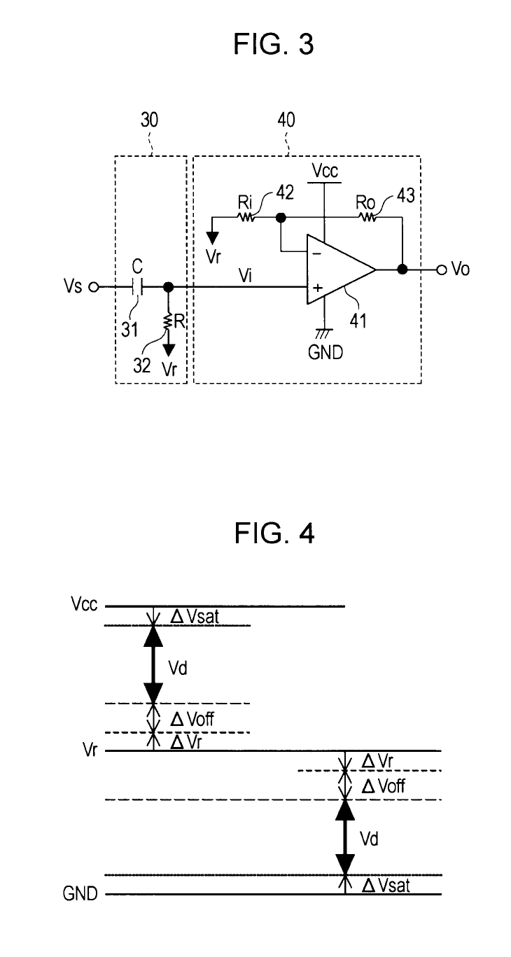

First, a basic amplification circuit of an angular velocity signal will be described with reference to FIG. 3. The amplification circuit is used as a basic amplification circuit which can be compared through description about the configuration and operation of an amplification circuit according to the embodiment, which will be described. FIG. 3 illustrates the basic amplification circuit.

(Basic Circuit)

The amplification circuit shown in FIG. 3 includes a non-inverting amplifier 40. A high pass filter 30 including a capacitor 31 and a resistor 32 are provided at an input side of the non-inverting amplifier 40. The non-inverting amplifier 40 includes an OP amp 41, a first negative feedback resistor 42 and a second negative feedback resistor 43. The first negative feedback resistor 42 is connected between a non-inverting input terminal (−) of the OP amp 41 and a reference potential Vr, and has a resistance value of Ri. The second negative feedback resistor 43 is connected between an output terminal of the OP amp 41 and the non-inverting input terminal (−) of the OP amp 41, and has a resistance value of Ro.

A detection signal Vs of the sensor device for detecting an angular velocity includes the reference potential Vr and an electrical signal corresponding to the angular velocity changing with respect to the reference potential Vr. Thus, the difference between the detection signal Vs and the reference potential Vr is obtained, so that a net angular velocity signal representing the magnitude of an angular velocity is extracted. Meanwhile, the electrical signal corresponding to the angular velocity changing with respect to the reference potential Vr has drift properties changing with the passage of time. Drift of the electrical signal corresponding to the angular velocity changing with respect to the reference potential Vr includes so-called start drift or temperature drift. The high pass filter 30 is used for removing drift components of the electrical signal corresponding to the angular velocity changing with respect to the reference potential Vr. Since the drift of the electrical signal corresponding to the angular velocity changing with respect to the reference potential Vr may be a significant obstruction during angular velocity detection, the drift is removed by the high pass filter 30 before the detection signal is amplified by the non-inverting amplifier 40.

A cut-off frequency of the high pass filter 30 is set enough to remove the drift components of the electrical signal corresponding to the angular velocity changing with respect to the reference potential Vr. If the capacitance of the capacitor 31 is defined as C and the value of the resistor 32 is defined as R, the cut-off frequency f_{c} of the high pass filter 30 is decided as 1/(2μRC), and is typically set to about 0.01 Hz.

In FIG. 3, the detection signal Vs serving as the output of the sensor device corresponds to an input voltage of the high pass filter 30. An output voltage V1 of the high pass filter 30 corresponds to a detection signal of the sensor device, which is obtained by removing the drift components of the electrical signal corresponding to the angular velocity changing with respect to the reference potential Vr by the high pass filter 30, and serves as an input voltage to a non-inverting input terminal (+) of the non-inverting amplifier 40. The non-inverting amplifier 40 amplifies the difference between the detection signal Vi of the sensor device and the reference potential Vr with a predetermined gain, thereby generating an output voltage V0 as an output signal.

Herein, one end of the resistor 32 and one end of the resistor 42 are connected to the reference potential Vr such that the high pass filter 30 and the non-inverting amplifier 40 are allowed to operate at a bias voltage corresponding to the reference potential Vr. The power of the OP amp 41 is connected to a power supply potential Vcc and the ground GND. In the following description, the reference potential Vr has an intermediate value of the power supply potential Vcc and the ground GND as expressed by Equation 1 below.

Vr=(Vcc+GND)/2 Equation 1

A gain of the non-inverting amplifier 40 is decided by the combination of the resistance values of the negative feedback resistor 42 and 43. That is, the gain of the non-inverting amplifier 40 is expressed by Equation 2 below and is normally set to about 50 times to 100 times.

Vo/Vi=1+(Ro/Ri) Equation 2

FIG. 4 is a schematic diagram illustrating an output dynamic range of the amplification circuit shown in FIG. 3. The output voltage V0 of the non-inverting amplifier 40 is equal to the reference potential Vr when an angular velocity is not added thereto. However, if an angular velocity in a predetermined direction is added, the output voltage V0 of the non-inverting amplifier 40 is changed to a potential higher than the reference potential Vr. Further, if an angular velocity in a direction opposite to the predetermined direction is added, the output voltage V0 of the non-inverting amplifier 40 is changed to a potential lower than the reference potential Vr. Ideally, the output voltage V0 has a value in a range of GND to Vcc about the reference potential Vr.

However, due to the existence of variation AVr of the reference potential Vr, variation AVoff of the offset of the non-inverting amplifier 40, variation AVsat of a saturation voltage decided by the circuit of the OP amp 41 and the like, the dynamic range (D range) in which a signal corresponding to an angular velocity can be output may be narrowed. When the dynamic range is defined as Vd, it is expressed by Equation 3 below.

$$\begin{matrix}Vd = Vr - GND - ( Δ Vr + Δ Voff + Δ Vsat ) \\ = Vcc - Vr - ( Δ Vr + Δ Voff + Δ Vsat )\end{matrix} \qquad Equation 3$$

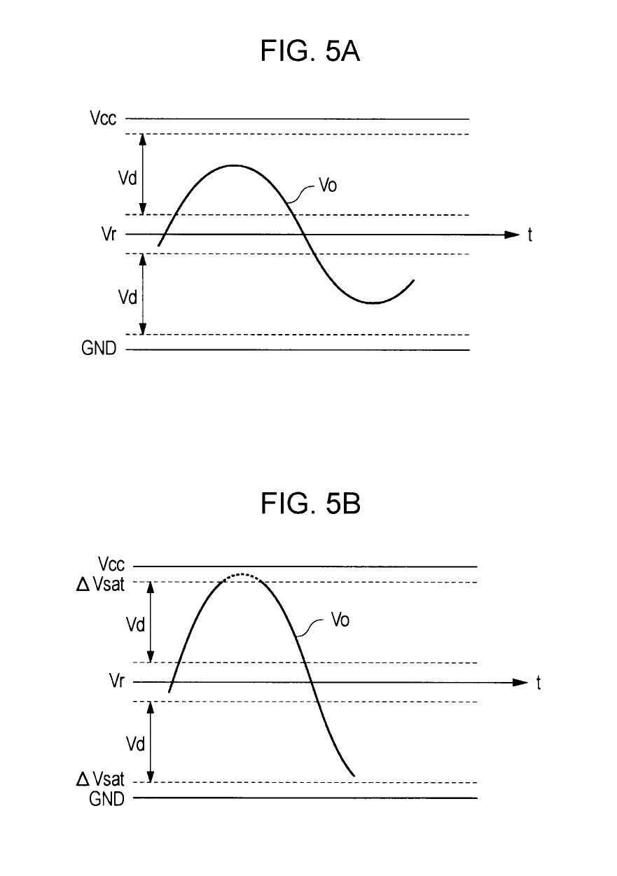

FIGS. 5A and 5B are schematic diagrams illustrating one example of variation of the output voltage V0 of the non-inverting amplifier 40 with respect to time. FIG. 5A illustrates an example in which an angular velocity is changed in the dynamic range Vd and FIG. 5B illustrates an example in which the angular velocity exceeds the dynamic range Vd and is changed. As illustrated in FIG. 5A, if the output voltage V0 exists in the dynamic range Vd, the angular velocity can be properly detected. However, as illustrated in FIG. 5B, if the output voltage V0 exceeds the dynamic range Vd, the angular velocity may not be properly detected. The fact that the dynamic range Vd is wide represents that an angular velocity detection range is wide. Thus, a wide dynamic range is ensured to allow the magnitude of the angular velocity to be detected in a wide range, so that angular velocity detection can be performed with high accuracy without limitation in the magnitude of the angular velocity. Since the dynamic range Vd is decided by the magnitude of the supply voltage Vcc, the wide dynamic range Vd can be ensured as the supply voltage Vcc is increased.

However, recently, power saving of an electronic apparatus is achieved and reduction of a supply voltage is necessary. Thus, in the non-inverting amplifier 40 shown in FIG. 3, it is inevitable that the dynamic range Vd is further narrowed as the supply voltage Vcc is reduced. Meanwhile, it is considered to ensure the dynamic range Vd by reducing the gain of the non-inverting amplifier 40. However, according to such a method, detection resolution of the angular velocity is significantly reduced, resulting in the difficulty in detecting a weak angular velocity signal with high accuracy.

The angular velocity sensor, the shake correction apparatus and the electronic apparatus according to the embodiment are provided with an amplification circuit capable of increasing an angular velocity detection range without reduction in angular velocity detection sensitivity. Hereinafter, the amplification circuit according to the embodiment will be described.

(Amplification Circuit According to First Embodiment)

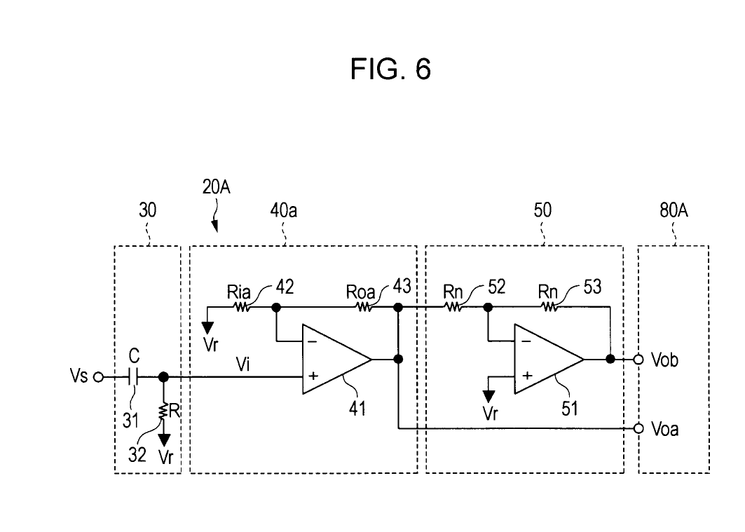

FIG. 6 is a circuit diagram illustrating the configuration of the amplification circuit of an angular velocity signal according to the first embodiment of the invention. The amplification circuit 20A of the embodiment has a configuration in which an inverting amplifier is added to the basic amplification circuit shown in FIG. 3. That is, the amplification circuit 20A of the embodiment includes a non-inverting amplifier 40a (first amplification circuit section) and an inverting amplifier 50 (second amplification circuit section). The high pass filter 30 is provided at an input side of the non-inverting amplifier 40a and a signal processing circuit 80A is provided at an output side of the inverting amplifier 50.

The high pass filter 30 includes the capacitor 31 and the resistor 32 to input the signal Vi, which is obtained by removing the drift components of the electrical signal corresponding to the angular velocity changing with respect to the reference potential Vr from the detection signal Vs, to the non-inverting input terminal (+) of the non-inverting amplifier 40a. The non-inverting amplifier 40a has a configuration equal to that of the non-inverting amplifier 40 shown in FIG. 3 and includes the OP amp 41, the first negative feedback resistor 42 and the second negative feedback resistor 43. The first and second negative feedback resistors 42 and 43 have resistance values of Ria and Roa, respectively. The inverting amplifier 50 includes an OP amp 51, a first negative feedback resistor 52 and a second negative feedback resistor 53. The first and second negative feedback resistors 52 and 53 have the same resistance value of Rn. An inverting input terminal (−) of the OP amp 51 is connected to an output terminal of the OP amp 41 through the resistor 52.

Herein, one end of the resistor 32, one end of the resistor 42, and the non-inverting input terminal (+) of the OP amp 51 are connected to the reference potential Vr such that the high pass filter 30, the non-inverting amplifier 40a and the inverting amplifier 50 are allowed to operate at a bias voltage corresponding to the reference potential Vr.

The non-inverting amplifier 40a outputs a first output signal Voa obtained by amplifying the difference between the detection signal Vi and the reference potential Vr with a first gain. The first output signal Voa is provided to the input terminal of the inverting amplifier 50. Further, the first output signal Voa is provided to the signal processing circuit 80A through the output terminal of the amplification circuit 20A. The non-inverting amplifier 40a generating the first output signal Voa constitutes the first amplification circuit section. Herein, a case will be described, in which the resistance value Roa and the resistance value Ria are set such that the first gain is equal to ½ of the gain of the non-inverting amplifier 40 shown in FIG. 3. That is, the gain of the non-inverting amplifier 40a is expressed by Equation 4 below.

Voa/Vi=1+(Roa/Ria)=(½)·(Vo/Vi) Equation 4

The inverting amplifier 50 outputs a second output signal Vob obtained by amplifying the difference between the first output signal Voa and the reference potential Vr with a second gain. The second output signal Vob is provided to the signal processing circuit 80A through the output terminal of the amplification circuit 20A. The inverting amplifier 50 generating the second output signal Vob constitutes the second amplification circuit section. Since the resistors 52 and 53 have the same value, the second gain is 1. That is, the second output signal Vob corresponds to an output signal obtained by inverting-amplifying the difference between the detection signal Vi and the reference potential Vr with the first gain, and is different from the first output signal Voa by polarity. Thus, the gain of the inverting amplifier 50 is expressed by Equation 5 below.

Vob/Vi=−Voa/Vi Equation 5

The signal processing circuit 80A generates an angular velocity signal based on the first output signal Voa and the second output signal Vob, and constitutes a part of the control circuit 91 (FIG. 2). The signal processing circuit 80A calculates the difference between the first output signal Voa and the second output signal Vob to generate the angular velocity signal. The first output signal Voa is in a differential relationship with the second output signal Vob about the reference potential Vr. In the signal processing circuit 80A, the gain when calculating (Voa−Vob) is expressed by Equation 6 below and is equal to the gain of the non-inverting amplifier 40 shown in FIG. 3.

(Voa−Vob)/Vi=2·Voa/Vi=Vo/Vi Equation 6

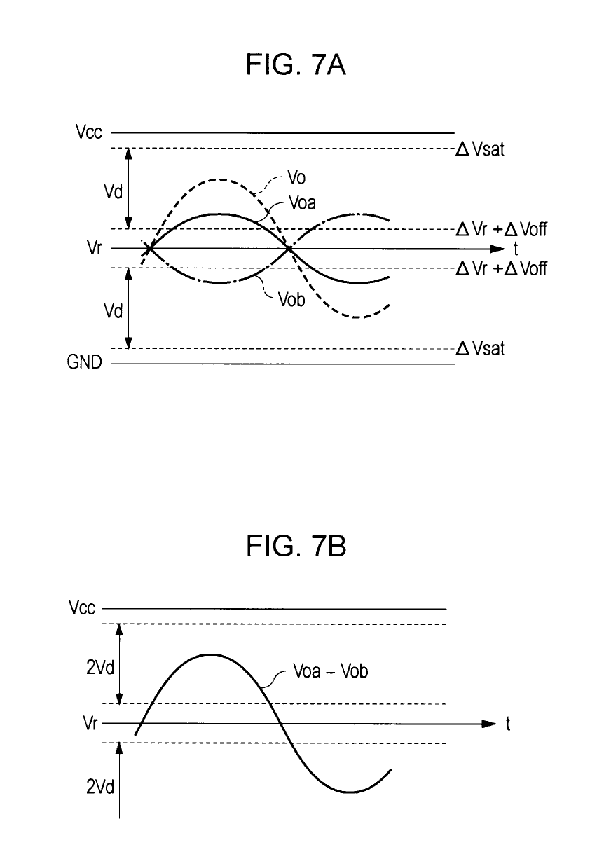

FIG. 7A is a schematic diagram illustrating one example of variation of the first and second output signals (output voltages) Voa and Vob with respect to time. The waveform indicated by a broken line of FIG. 7A represents the output signal Vo of the basic amplification circuit shown in FIG. 5A. Since the gains of the non-inverting amplifier 40a and the inverting amplifier 50 correspond to ½ of the gain of the basic amplification circuit 40, the first and second output signals Voa and Vob have a magnitude corresponding to ½ of the output signal Vo. The dynamic range of the output signals Voa and Vob corresponds to Vd described with reference to FIG. 4.

Meanwhile, FIG. 7B is a schematic diagram illustrating variation of the output signal (Voa−Vob), which is obtained by calculating the difference between the output signal Voa and the output signal Vob, with respect to time in the signal processing circuit 80A. Since the output signal Voa is in a differential relationship with the output signal Vob about the reference potential Vr, the difference between the two signals is obtained, so that a dynamic range 2·Vd which is twice as wide as the dynamic range Vd is acquired. Further, as expressed by Equation 6 above, the amplification circuit 20A of the embodiment has a gain equal to that of the basic amplification circuit, so that the angular velocity signals can be generated without reduction in the detection sensitivity.

As described above, according to the embodiment, it is possible to ensure the angular velocity detection range which is twice as wide as the dynamic range Vd while maintaining the output sensitivity of the angular velocity. Further, the total gain of the amplification circuit 20A is divided by the first and second amplification circuit sections, so that the output signals exceeding the dynamic range Vd can be generated without being saturated. Consequently, the angular velocity can be detected with high accuracy in a wide range. In addition, it is possible to cope with the reduction of the supply voltage Vcc, resulting in the contribution to the miniaturization and low power consumption of the apparatus.

The signal processing circuit 80A (or the control circuit 91 including this) generates the correction signal for driving the shake correction mechanism 92 based on the angular velocity signals obtained as described above. The signal processing circuit 80A converts the angular velocity signal (analog signal) into a digital signal by using the A/D convertor to generate the correction signal. Consequently, blurring of an object image, which is caused by a shake occurring in the casing 2 of the camera 1, can be prevented, so that the probability of the generation of a failed photograph can be significantly reduced.

Moreover, in the embodiment, the angular velocity is detected in two directions, that is, the yaw direction and the pitch direction, so that the amplification circuit 20A having the above configuration is individually used for detecting the angular velocity in each direction.

[Modified Example of First Embodiment]

In the example of FIG. 6, the case in which the amplification circuit 20A includes the combination of the non-inverting amplifier 40a and the inverting amplifier 50 has been described. However, the invention is not limited thereto. For example, the amplification circuit may include the combination of an inverting amplifier and another inverting amplifier.

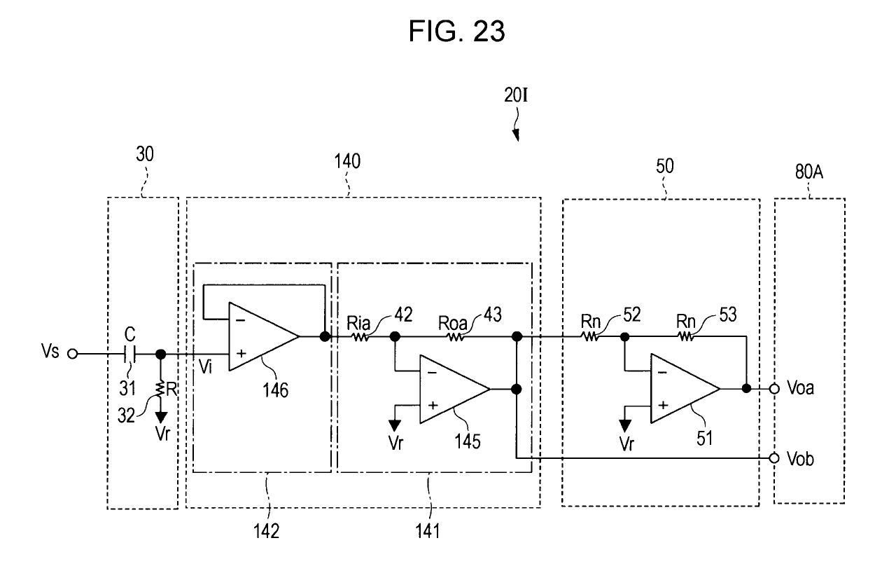

FIG. 23 is a circuit diagram illustrating one example in which the amplification circuit includes the combination of an inverting amplifier and another inverting amplifier.

As shown in FIG. 23, the amplification circuit 20I includes an inverting amplifier 140 (first amplification circuit section) and an inverting amplifier 50 (second amplification circuit section). The high pass filter 30 is provided at an input side of the inverting amplifier 140 and the signal processing circuit 80A is provided at an output side of the inverting amplifier 50.

The inverting amplifier 140 includes an inverting amplifying portion 141 having an OP amp 145, the first negative feedback resistor 42 and the second negative feedback resistor 43, and a voltage follower 142 having an OP amp 146.

The OP amp 145 of the inverting amplifying portion 141 has a non-inverting input terminal (+) connected to the reference potential Vr and an inverting input terminal (−) connected to an output terminal of the OP amp 146 of the voltage follower 142 through the resistor 42.

The first and second negative feedback resistors 42 and 43 of the inverting amplifying portion 141 have resistance values of Ria and Roa, respectively.

The OP amp 146 of the voltage follower 142 has a non-inverting input terminal (+) connected to an output side of the high pass filter 30. The voltage follower 142 is used for impedance-converting the output of the high pass filter 30.

The inverting amplifier 50 has a configuration equal to that of the inverting amplifier 50 described in FIG. 6, and includes the OP amp 51, the first negative feedback resistor 52 and the second negative feedback resistor 53. The first and second negative feedback resistors 52 and 53 have the same resistance value of Rn.

(Operation Description)

The voltage follower 142 converts the detection signal Vi having passed through the high pass filter 30 into a low impedance signal from a high impedance signal, and outputs the low impedance signal to the inverting amplifying portion 141. Consequently, the first negative feedback resistor 42 is affected by the influence of impedance of the high pass filter 30, so that the output of the inverting amplifying portion 141 can be prevented from being reduced.

The inverting amplifying portion 141 outputs the signal Vob (second output signal) obtained by inverting-amplifying the difference between the signal output from the voltage follower 142 and the reference potential Vr. In such a case, since the first and second negative feedback resistors 42 and 43 each have the resistance values of Ria and Roa, the signal Vob, which is obtained by inverting-amplifying the detection signal Vi with the gain (Roa/Ria), that is, the signal Vob, which is obtained by amplifying the detection signal Vi with the gain (−Roa/Ria), is output from the inverting amplifying portion 141.

The signal Vob output from the inverting amplifying portion 141 is provided to the inverting input terminal (−) of the inverting amplifier 50. Further, the second output signal Vob is provided to the signal processing circuit 80A through the output terminal of the amplification circuit 20I.

The inverting amplifier 50 outputs the signal Voa (first output signal) obtained by inverting-amplifying the difference between the signal Vob and the reference potential Vr. In such a case, since the first and second negative feedback resistors 52 and 53 have the same resistance value of Rn, the signal Voa, which is obtained by inverting-amplifying the signal Vob with the gain having a value of 1, that is, the signal Voa, which is obtained by amplifying the signal Vob with the gain having a value of −1, is output from the inverting amplifier 50. The signal Voa is provided to the signal processing circuit 80A through the output terminal of the amplification circuit 20I.

Since the signal Voa is obtained by inverting-amplifying the signal Vob with the gain having a value of 1, the signals Voa and Vob have the same magnitude, but have polarities different from each other.

Herein, since the signal Voa is obtained by inverting-amplifying the detection signal Vi twice, the detection signal Vi is a non-inverting amplified signal. Meanwhile, since the signal Vob is obtained by inverting-amplifying the detection signal Vi once, the detection signal Vi is an inverting-amplified signal.

The signal processing circuit 80A calculates the difference between the signal Voa and the signal Vob to generate the angular velocity signal.

According to the modified example shown in FIG. 23, the same effect as that obtained in the first embodiment can be obtained. That is, since the signal Voa is in a differential relationship with the signal Vob about the reference potential Vr, the difference between the two signals is obtained, so that a dynamic range 2·Vd which is twice as wide as the dynamic range Vd of the basic amplification circuit can be acquired. Further, the amplification circuit 20I has a gain equal to that of the basic amplification circuit, so that the angular velocity signals can be generated without reduction in the detection sensitivity.

### Second Embodiment

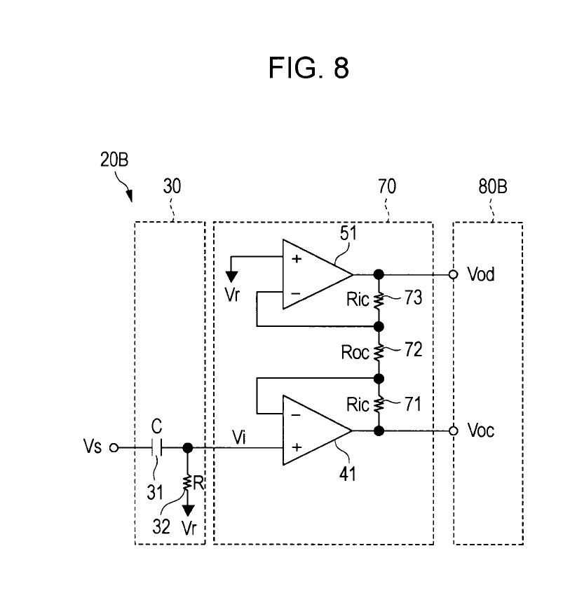

FIG. 8 is a circuit diagram illustrating the configuration of an amplification circuit of an angular velocity signal according to the second embodiment of the invention. In FIG. 8, the same reference numerals are used to designate the same elements as those of FIG. 6, and detailed description thereof will be omitted in order to avoid redundancy.

The amplification circuit 20B of the embodiment includes an amplification circuit section 70. The high pass filter 30 is provided at an input side of the amplification circuit section 70 and a signal processing circuit 80B is provided at an output side of the amplification circuit section 70.

The amplification circuit section 70 includes the first OP amp 41, the second OP amp 51, a first resistor 71, a second resistor 72 and a third resistor 73. The resistors 71 to 73 are serially connected between an output terminal of the OP amp 41 and an output terminal of the OP amp 51, and have resistance values of Ric, Roc and Ric, respectively. The first OP amp 41 has a non-inverting input terminal (+) connected to the high pass filter 30 and an inverting input terminal (−) connected between the first resistor 71 and the second resistor 72. The second OP amp 51 has a non-inverting input terminal (+) connected to the reference potential Vr and an inverting input terminal (−) connected between the second resistor 72 and the third resistor 73.

In the embodiment, the gain of the amplification circuit section 70 is set to be equal to that of the basic amplification circuit which is expressed by Equation 2 above. If an input voltage of the first OP amp 41 is defined as Vi, an output voltage of the first OP amp 41 is defined as Voc and an output voltage of the second OP amp 51 is defined as Vod, the gain of the amplification circuit section 70 is expressed by Equation 7 below. The output voltage Voc corresponds to the first output signal generated by non-inverting amplifying the detection signal Vi in the first OP amp 41. The output voltage Vod corresponds to the second output signal generated by inverting-amplifying the detection signal Vi in the first OP amp 41 and the second OP amp 51.

(Voc−Vod)/Vi=1+(2·Ric/Roc)=Vo/Vi Equation 7

The signal processing circuit 80B calculates the difference between the first output signal Voc and the second signal Vod to generate an angular velocity signal. The output signal Voc is in a differential relationship with the output signal Vod about the reference potential Vr, the difference between the two signals is obtained, so that a dynamic range 2·Vd which is twice as wide as the dynamic range Vd of the basic amplification circuit can be acquired. Further, the amplification circuit 20B has a gain equal to that of the basic amplification circuit, so that the angular velocity signals can be generated without reduction in the detection sensitivity.

As described above, according to the embodiment, the same effect as that obtained in the first embodiment can be obtained. The amplification circuit 20B of the embodiment can be formed with the same configuration as that of the amplification circuit 20 shown in FIG. 2. In addition, the angular velocity is detected in two directions, that is, the yaw direction and the pitch direction, so that the amplification circuit 20B having the above configuration is individually used for detecting the angular velocity in each direction.

### Third Embodiment

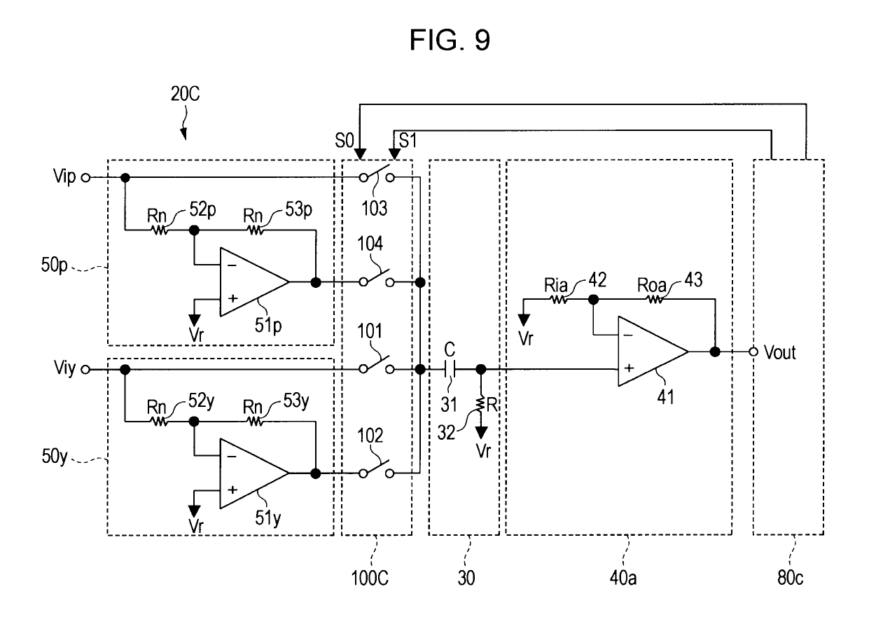

FIG. 9 is a circuit diagram illustrating the configuration of an amplification circuit of an angular velocity signal according to the third embodiment of the invention. In FIG. 9, the same reference numerals are used to designate the same elements as those of FIG. 6, and detailed description thereof will be omitted in order to avoid redundancy.

The amplification circuit 20C of the embodiment includes the non-inverting amplifier 40a (first amplification circuit section), a first inverting amplifier 50y (second amplification circuit section), and a second inverting amplifier 50p (second amplification circuit section). A switch circuit 100C is provided between the first and second inverting amplifiers 50y and 50p and the non-inverting amplifier 40a, and a signal processing circuit 80C is provided at an output side of the non-inverting amplifier 40a.

The first and second inverting amplifiers 50y and 50p each have the same configuration as that of the inverting amplifier 50 shown in FIG. 6. In detail, the first inverting amplifier 50y includes an OP amp 51y, a first negative feedback resistor 52y and a second negative feedback resistor 53y, and the second inverting amplifier 50p includes an OP amp 51p, a first negative feedback resistor 52p and a second negative feedback resistor 53p. The resistors 52y, 52p, 53y and 53p have the same resistance value of Rn. Output sides of the first and second inverting amplifiers 50y and 50p are connected to the high pass filter 30 through the switch circuit 100C, and an output side of the high pass filter 30 is connected to the non-inverting input terminal (+) of the non-inverting amplifier 40a.

The sensor device 10y for detecting the angular velocity of the yaw direction outputs a detection signal Viy and the sensor device 10p for detecting the angular velocity of the pitch direction outputs a detection signal Vip. The detection signals Viy and Vip can be configured to be input to the high pass filter 30 through the switch circuit 100C. The high pass filter 30 removes drift components of the electrical signal corresponding to the angular velocity changing with respect to the reference potential Vr from various input signals output from the switch circuit 100C. The non-inverting amplifier 40a generates output signals Voy1 and Vop1 (first output signals) by non-inverting amplifying the detection signals Viy and Vip having passed through the high pass filter 30 with the first gain (first amplification circuit section).

Further, the detection signals Viy and Vip are input to input terminals of the first and second inverting amplifiers 50y and 50p, respectively. The first and second inverting amplifiers 50y and 50p generate output signals Viy2 and Vip2 (third output signals) by inverting-amplifying the detection signals Viy and Vip with a gain having a value of 1. Then, the first and second inverting amplifiers 50y and 50p input the output signals Viy2 and Vip2 to the non-inverting amplifier 40a, thereby allowing output signals Voy2 and Vop2 (second output signals) to be generated by non-inverting amplifying the output signals with the gain having a value of 1 (second amplification circuit section). Herein, between the third output signals output from the first and second inverting amplifiers 50y and 50p, the signal Viy2 output from the first inverting amplifier 50y will be referred to as a fourth output signal and the signal Vip2 output from the second inverting amplifier 50p will be referred to as a fifth output signal.

The switch circuit 100C includes four switch sections 101 to 104. The switch section 101 switches the input and cutoff of the detection signal Viy to the non-inverting amplifier 40a, the switch section 102 switches the input and cutoff of the output signal Viy2 of the first inverting amplifier 50y to the non-inverting amplifier 40a, the switch section 103 switches the input and cutoff of the detection signal Vip to the non-inverting amplifier 40a, and the switch section 104 switches the input and cutoff of the output signal Vip2 of the second inverting amplifier 50p to the non-inverting amplifier 40a.

The switch sections (bilateral switches) 101 to 104 are switched by select signals S0 and S1 which are input to the switch circuit 100C from the signal processing circuit 80C. The select signals S0 and S1 each are at a high level and a low level, and a switch section to be turned on is determined by the combination of these signal levels. When one switch section is turned on, the remaining switch sections are turned off.

In the embodiment, when all the signals S0 and S1 are at a low level, the switch section 101 is turned on. When all the signals S0 and S1 are at a high level, the switch section 104 is turned on. Further, when the signal S0 is at a low level and the signal S1 is at a high level, the switch section 102 is turned on. When the signal S0 is at a high level and the signal S1 is at a low level, the switch section 103 is turned on.

The switch circuit 100C selectively switches a first state in which the first output signal Voy1 or Vop1 is output from the amplification circuit 20C and input to the signal processing circuit 80C, and a second state in which the second output signal Voy2 or Vop2 is output from the amplification circuit 20C and input to the signal processing circuit 80C. According to the embodiment, the first state is classified into a first switching state in which the first output signal Voy1 is input to the signal processing circuit 80C and a second switching state in which the first output signal Vop1 is output from the amplification circuit 20C. Meanwhile, the second state is classified into a third switching state in which the second output signal Voy2 is output from the amplification circuit 20C and a fourth switching state in which the second output signal Vop2 is output from the amplification circuit 20C.

Thus, in the amplification circuit 20C shown in FIG. 9, the first switching state is established when the switch section 101 is turned on and the second switching state is established when the switch section 103 is turned on. Further, the third switching state is established when the switch section 102 is turned on and the fourth switching state is established when the switch section 104 is turned on. In such a case, the switch sections 101 and 103 correspond to a first switch circuit section capable of limiting the input of the detection signals Viy and Vip to the first amplification circuit section (the non-inverting amplifier 40a). Further, the switch sections 102 and 104 correspond to a second switch circuit section capable of limiting the input of the third output signals (fourth output signal Viy2 and fifth output signal Vip2) to the first amplification circuit section (the non-inverting amplifier 40a).

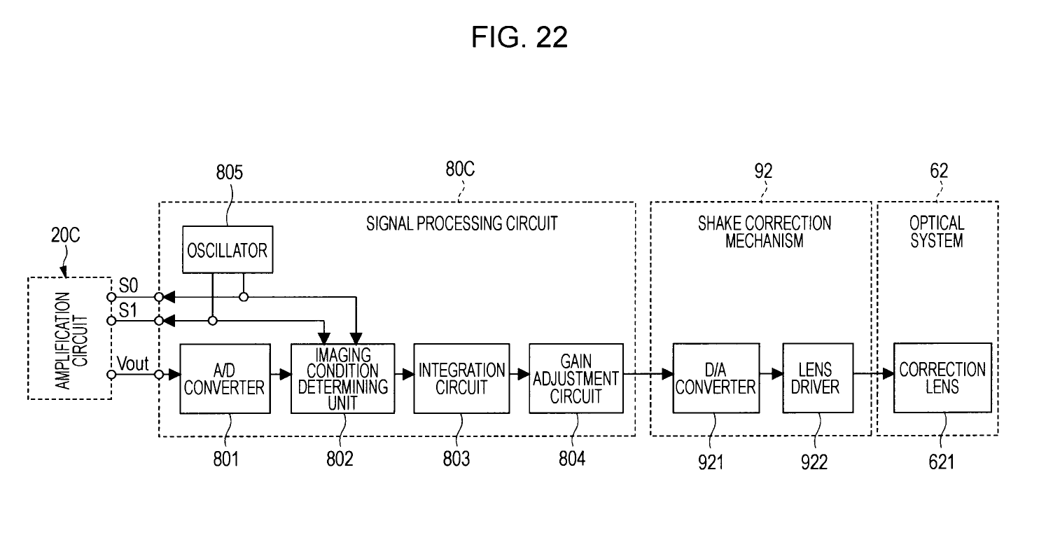

FIG. 22 is a block diagram illustrating the configuration of the controller 90 (FIG. 2) including the signal processing circuit 80C. The signal processing circuit 80C includes an A/D converter 801, an imaging condition determining unit 802, an integration circuit 803, a gain adjustment circuit 804 and an oscillator 805. The shake correction mechanism 92 includes a D/A converter 921 and a lens driver 922.

An output signal Vout from the amplification circuit 20C corresponds to a time-series analog signal including a differential signal. This signal is input to the signal processing circuit 80C, and then is converted into a digital signal by the A/D converter 801. Further, the signal Vout is controlled by digital signals S0 and S1 from the oscillator 805. The imaging condition determining unit 802 has a memory enough to store the signal Vout, and calculates the difference between the first output signals Voy1 and Vop1 and the second output signals Voy2 and Vop2 to generate the angular velocity signal. That is, the imaging condition determining unit 802 calculates the difference between Voy1 and Voy2 to generate the angular velocity signal in the yaw direction, and calculates the difference between Vop1 and Vop2 to generate the angular velocity signal in the pitch direction. The imaging condition determining unit 802 individually recognizes the time-series signal, and estimates panning and the state of a tripod of the camera based on the behavior of the time-series signal. According to the estimation, the integration circuit 803 controls integration for converting the signal Vout into a shake angle. The gain adjustment circuit 804 performs gain adjustment according to the shake angle and zoom, and focus states, thereby obtaining a signal corresponding to a target value of shake correction. The determined signal with the target value is input to the D/A converter 921 of the shake correction mechanism 92 so as to be converted into an analog signal. This signal is input to the lens driver 922 to drive a correction lens 621 of the optical system 62 (FIG. 2), resulting in the performance of the shake correction.

In the amplification circuit 20C having the configuration as described above according to the embodiment, output Vy1 of the sensor device 10y of the yaw direction and output Vp1 of the sensor device 10p of the pitch direction are independently input. The switch circuit 100C sequentially switches the switch sections 101 to 104 based on the select signals S0 and S1 provided from the signal processing circuit 80C, so that the signals Viy, Viy2, Vip and Vip2 are converted into time-series signals and input to the high pass filter 30 and the non-inverting amplifier 40a.

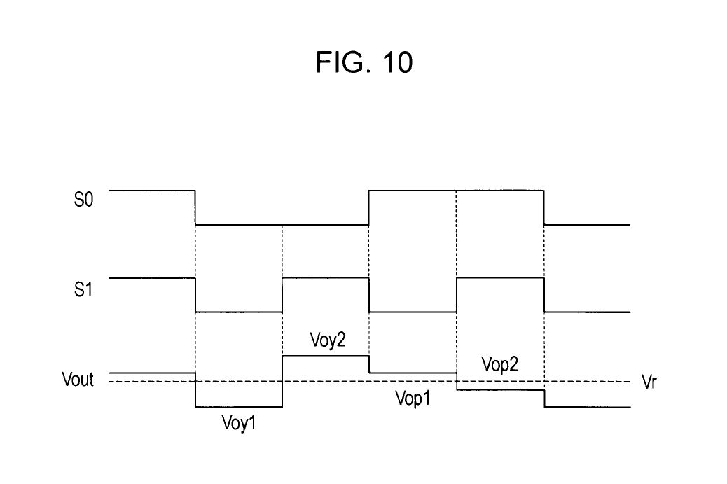

The non-inverting amplifier 40a amplifies an input signal, which is obtained by removing drift components of the electrical signal corresponding to the angular velocity changing with respect to the reference potential Vr by the high pass filter 30, with the first gain (1+(Roa/Ria)), and inputs a resultant output signal Vout to the signal processing circuit 80C. The output signal Vout of the non-inverting amplifier 40a corresponds to a time-series signal of Voy1, Voy2, Vop1 and Vop2. FIG. 10 is a diagram illustrating one example of variation of the signal levels of the select signals S0 and S1 with respect to time and variation of the output signal Vout of the non-inverting amplifier 40a with respect to time. In the example of FIG. 10, the non-inverting amplifier 40a generates the output signals in the sequence of Voy1, Voy2, Vop1 and Vop2. Further, the embodiment describes an example in which the angular velocity of the yaw direction is larger than the angular velocity of the pitch direction. However, the invention is not limited thereto.

The signal processing circuit 80C sequentially receives the output signals from the non-inverting amplifier 40a, and calculates a differential signal between Voy1 and Voy2 and a differential signal between Vop1 and Vop2, thereby generating angular velocity signals of the yaw direction and the pitch direction, respectively. Since the output signal Voy1 is in a differential relationship with the output signal Voy2 about the reference potential Vr and the output signal Vop1 is in a differential relationship with the output signal Vop2 about the reference potential Vr, the difference between the two signals Voy1 and Voy2 and the difference between the two signals Vop1 and Vop2 are obtained, so that a dynamic range 2·Vd which is twice as wide as the dynamic range Vd of the basic amplification circuit is acquired. Further, the amplification circuit 20C of the embodiment has a gain equal to that of the basic amplification circuit, so that the angular velocity signals can be generated without reduction in the detection sensitivity.

Further, according to the embodiment, the single non-inverting amplifier 40a can perform an amplification process with respect to the detection signals of the yaw direction and the pitch direction, resulting in the reduction of the number of parts. In addition, since the output signals Voy1, Voy2, Vop1 and Vop2 are input to the signal processing circuit 80C in time-series, it is advantageous in that one input terminal and one A/D converter is necessary for the signal processing circuit 80C.

A switching frequency of the first to fourth switching states made by the switch sections 101 to 104 of the switch circuit 100C can be set to 400 Hz or more. Since a detection frequency of angular velocities of the yaw direction and the pitch direction is equal to or less than 100 Hz (10 msec), the switching frequency of the switching states is set to 400 Hz or more (switching time is equal to or less than 1 msec), so that the angular velocity of each direction can be detected with high accuracy at a frequency of 100 Hz or less. In general, as the shutter speed of a camera is slow (exposure time is long), a photograph blurred by shaking may be easily generated. In this regard, in order to effectively prevent the generation of the photograph blurred by shaking, it is preferred to increase the shutter speed. For example, the shutter speed may be set to 4 msec or less. In such a case, the switching frequency is set such that each switching state is continued for 1 msec or less, thereby effectively preventing the generation of the photograph blurred by shaking.

### Fourth Embodiment

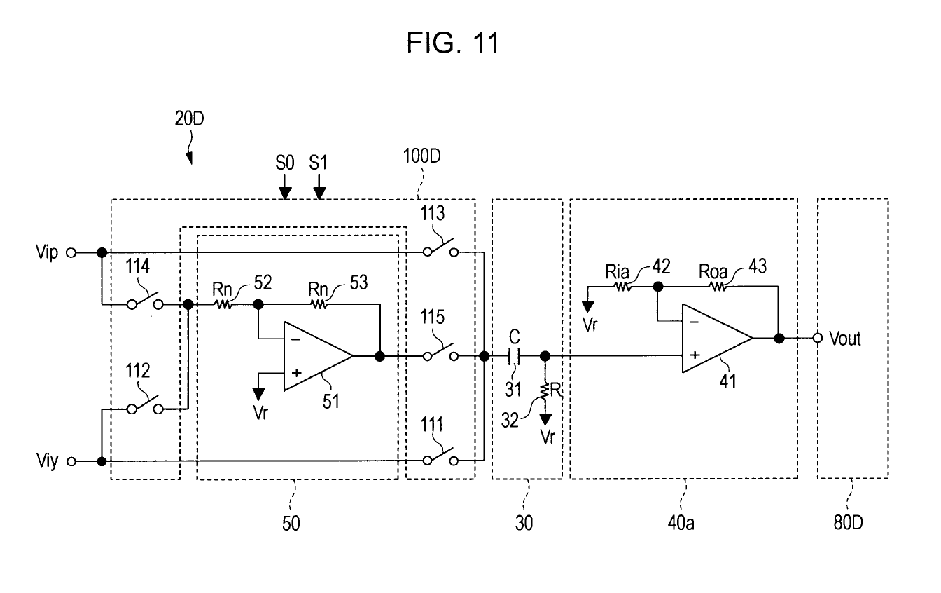

FIG. 11 is a circuit diagram illustrating the configuration of an amplification circuit of an angular velocity signal according to the fourth embodiment of the invention. In FIG. 11, the same reference numerals are used to designate the same elements as those of FIG. 6, and detailed description thereof will be omitted in order to avoid redundancy.

The amplification circuit 20D of the embodiment includes the non-inverting amplifier 40a (first amplification circuit section) and the inverting amplifier 50 (second amplification circuit section). A switch circuit 100D is provided at input and output sides of the inverting amplifier 50. Further, the high pass filter 30 is provided at an input side of the non-inverting amplifier 40a and a signal processing circuit 80D is provided at an output side of the non-inverting amplifier 40a.

The inverting amplifier 50 has the same configuration as that of the inverting amplifier 50 shown in FIG. 6. An output side of the inverting amplifier 50 is connected to the high pass filter 30 through the switch circuit 100D, and an output side of the high pass filter 30 is connected to the non-inverting input terminal (+) of the non-inverting amplifier 40a.

The sensor device 10y for detecting the angular velocity of the yaw direction outputs the detection signal Viy and the sensor device 10p for detecting the angular velocity of the pitch direction outputs the detection signal Vip. The detection signals Viy and Vip can be configured to be input to the high pass filter 30 through the switch circuit 100D. The high pass filter 30 removes drift components of the electrical signal corresponding to the angular velocity changing with respect to the reference potential Vr from various input signals output from the switch circuit 100D. The non-inverting amplifier 40a generates output signals Voy1 and Vop1 (first output signals) by non-inverting amplifying the detection signals Viy and Vip having passed through the high pass filter 30 with the first gain (first amplification circuit section).

Further, the detection signals Viy and Vip are input to an input terminal of the inverting amplifier 50 through the switch circuit 100D. The inverting amplifier 50 generates output signals Viy2 and Vip2 (third output signals) by inverting-amplifying the detection signals Viy and Vip with a gain having a value of 1. Then, the inverting amplifier 50 inputs the output signals Viy2 and Vip2 to the non-inverting amplifier 40a, thereby allowing output signals Voy2 and Vop2 (second output signals) to be generated by non-inverting amplifying the output signals with the gain having a value of 1 (second amplification circuit section). In the embodiment, the output signal Viy2 (fourth output signal) related to the detection signal Viy and the output signal Vip2 (fifth output signal) related to the detection signal Vip are generated by the single inverting amplifier 50. Input of the detection signals Viy and Vip to the inverting amplifier 50 is controlled by the switch circuit 100D.

The switch circuit 100D includes five switch sections 111 to 115. The switch section 111 switches the input and cutoff of the detection signal Viy to the non-inverting amplifier 40a, the switch section 112 switches the input and cutoff of the detection signal Viy to the inverting amplifier 50, the switch section 113 switches the input and cutoff of the detection signal Vip to the non-inverting amplifier 40a, the switch section 114 switches the input and cutoff of the detection signal Vip to the inverting amplifier 50, and the switch section 115 switches the input and cutoff of the output signals Viy2 and Vip2 of the inverting amplifier 50 to the non-inverting amplifier 40a.

The switch sections (bilateral switches) 111 to 115 are switched by the select signals S0 and S1 which are input to the switch circuit 100D from the signal processing circuit 80D. The select signals S0 and S1 each are at a high level and a low level, and a switch section to be turned on is determined by the combination of these signal levels. When one or two switch sections are turned on, the remaining switch sections are turned off.

In the embodiment, when all the signals S0 and S1 are at a low level, the switch section 111 is turned on. When all the signals S0 and S1 are at a high level, the switch sections 114 and 115 are turned on. Further, when the signal S0 is at a low level and the signal S1 is at a high level, the switch sections 112 and 115 turned on. When the signal S0 is at a high level and the signal S1 is at a low level, the switch section 113 is turned on.

The switch circuit 100D selectively switches a first state in which the first output signal Voy1 or Vop1 is output from the amplification circuit 20D, and a second state in which the second output signals Voy2 or Vop2 is output from the amplification circuit 20D. According to the embodiment, the first state is classified into a first switching state in which the first output signal Voy1 is output from the amplification circuit 20D, and a second switching state in which the first output signal Vop1 is output from the amplification circuit 20D. Meanwhile, the second state is classified into a third switching state in which the second output signal Voy2 is output from the amplification circuit 20D, and a fourth switching state in which the second output signal Vop2 is output from the amplification circuit 20D.

Thus, in the amplification circuit 20D shown in FIG. 11, the first switching state is established when the switch section 111 is turned on and the second switching state is established when the switch section 113 is turned on. Further, the third switching state is established when the switch sections 112 and 115 are turned on and the fourth switching state is established when the switch sections 114 and 115 are turned on. In such a case, the switch sections 111 and 113 correspond to a first switch circuit section capable of limiting the input of the detection signals Viy and Vip to the first amplification circuit section (the non-inverting amplifier 40a). Further, the switch sections 112, 114 and 115 correspond to a second switch circuit section capable of limiting the input of the third output signals (fourth output signal Viy2 and fifth output signal Vip2) to the first amplification circuit section (the non-inverting amplifier 40a).

The signal processing circuit 80D includes a signal generator for generating the select signals S0 and S1 input to the switch circuit 100D, and a memory enough to store the signals output from the non-inverting amplifier 40a. Further, the signal processing circuit 80D calculates the difference between the first output signals (Voy1, Vop1) and the second output signals (Voy2, Vop2), which are output from the non-inverting amplifier 40a, thereby generating angular velocity signals. That is, the signal processing circuit 80D calculates the difference between Voy1 and Voy2 to generate the angular velocity signal of the yaw direction, and calculates the difference between Vop1 and Vop2 to generate the angular velocity signal of the pitch direction.

In the amplification circuit 20D having the configuration as described above according to the embodiment, the switch circuit 100D sequentially switches the switch sections 111 to 115 based on the select signals S0 and S1 provided from the signal processing circuit 80D, so that the signals Viy, Viy2, Vip and Vip2 are converted into time-series signals and input to the high pass filter 30 and the non-inverting amplifier 40a. When the detection signal Viy is input, the inverting amplifier 50 inversion-amplifies the detection signal Viy with a gain having a value of 1 to generate the fourth output signal Viy2. When the detection signal Vip is input, the inverting amplifier 50 inversion-amplifies the detection signal Vip with the gain having a value of 1 to generate the fifth output signal Vip2.

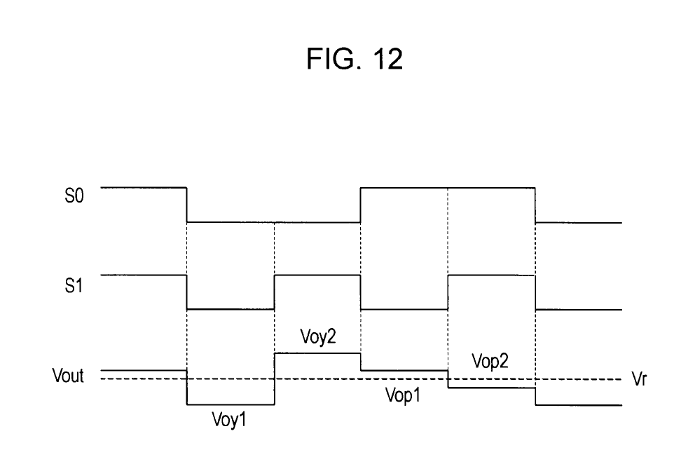

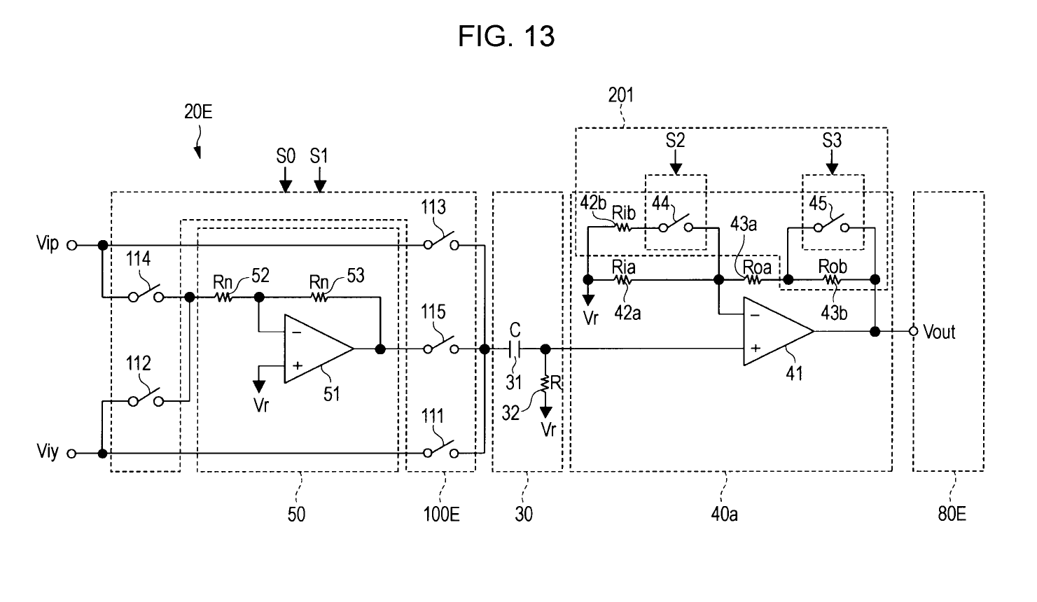

The non-inverting amplifier 40a amplifies an input signal, which is obtained by removing drift components of the electrical signal corresponding to the angular velocity changing with respect to the reference potential Vr by using the high pass filter 30, with the first gain (1+(Roa/Ria)), and inputs a resultant output signal Vout to the signal processing circuit 80D. The output signal Vout of the non-inverting amplifier 40a corresponds to a time-series signal of Voy1, Voy2, Vop1 and Vop2. FIG. 12 is a diagram illustrating one example of variation of the signal levels of the select signals S0 and S1 with respect to time and variation of the output signal Vout of the non-inverting amplifier 40a with respect to time. In the example of FIG. 12, the non-inverting amplifier 40a generates the output signals in the sequence of Voy1, Voy2, Vop1 and Vop2. Further, the embodiment describes an example in which the angular velocity of the yaw direction is larger than the angular velocity of the pitch direction. However, the invention is not limited thereto.

The signal processing circuit 80D sequentially receives the output signals from the non-inverting amplifier 40a, and calculates a differential signal between Voy1 and Voy2 and a differential signal between Vop1 and Vop2, thereby generating angular velocity signals of the yaw direction and the pitch direction, respectively. Since the output signal Voy1 is in a differential relationship with the output signal Voy2 about the reference potential Vr and the output signal Vop1 is in a differential relationship with the output signal Vop2 about the reference potential Vr, the difference between the two signals Voy1 and Voy2 and the difference between the two signals Vop1 and Vop2 are obtained, so that a dynamic range 2·Vd which is twice as wide as the dynamic range Vd of the basic amplification circuit is acquired. Further, the amplification circuit 20D of the embodiment has a gain equal to that of the basic amplification circuit, so that the angular velocity signals can be generated without reduction in the detection sensitivity.

Further, according to the embodiment, the single non-inverting amplifier 40a and the single inverting amplifier 50 can perform an amplification process with respect to the detection signals of the yaw direction and the pitch direction, resulting in the reduction of the number of parts. In addition, since the output signals Voy1, Voy2, Vop1 and Vop2 are input to the signal processing circuit 80D in time-series, it is advantageous in that one input terminal and one A/D converter is necessary for the signal processing circuit 80D.

Even in the embodiment, a switching frequency of the first to fourth switching states of the switch circuit 100D is set to 400 Hz or more. Consequently, the angular velocities of the yaw direction and the pitch direction can be detected with high accuracy. Further, the switching frequency is set such that each switching state is continued for 1 msec or less, thereby effectively preventing the generation of a photograph blurred by shaking.

[Modified Example of Fourth Embodiment]

Next, the modified example of the fourth embodiment will be described. In the modified example of the fourth embodiment, a case in which an amplification circuit includes the combination of an inverting amplifier and another inverting amplifier will be described.

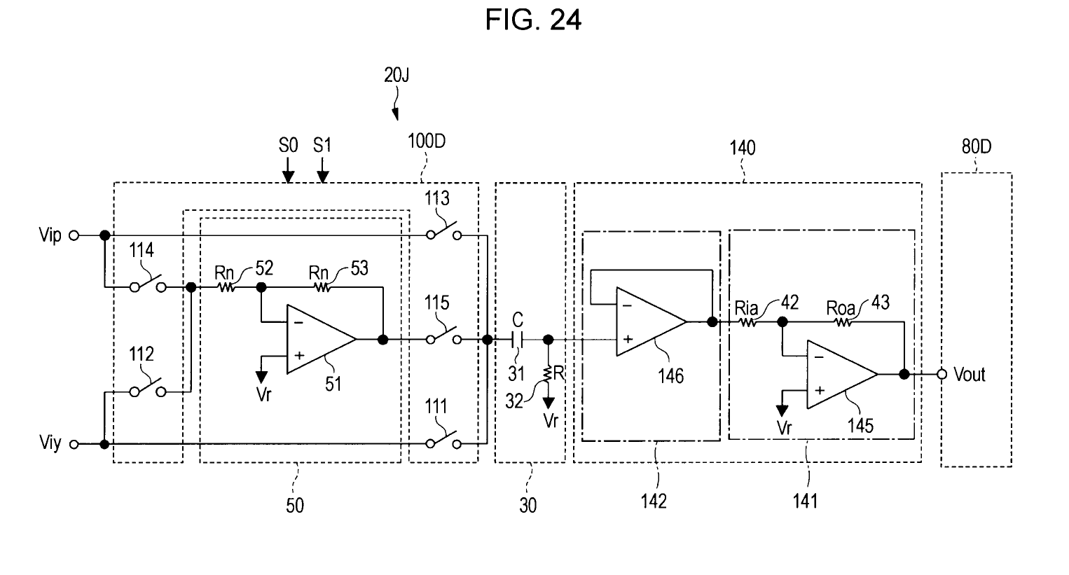

FIG. 24 is a circuit diagram illustrating one example in which the amplification circuit includes the combination of an inverting amplifier and another inverting amplifier.

As shown in FIG. 24, in the amplification circuit 20J according to the modified example, the non-inverting amplifier 40a shown in FIG. 11 is replaced with an inverting amplifier 140.

The inverting amplifier 140 has the same configuration as that of the inverting amplifier 140 described in FIG. 23 and includes the inverting amplifying portion 141 having the OP amp 145, the first negative feedback resistor 42 and the second negative feedback resistor 43, and the voltage follower 142 having the OP amp 146.

The switch circuit 100D sequentially switches the switch sections 111 to 115 based on the select signals S0 and S1 provided from the signal processing circuit 80D, so that the signals Viy, Viy2, Vip and Vip2 are converted into time-series signals and input to the high pass filter 30 and the inverting amplifier 140. When the detection signal Viy is input, the inverting amplifier 50 inversion-amplifies the detection signal Viy with a gain having a value of 1 to generate the output signal Viy2. When the detection signal Vip is input, the inverting amplifier 50 inversion-amplifies the detection signal Vip with the gain having a value of 1 to generate the output signal Vip2.

The voltage follower 142 of the inverting amplifier 140 converts an input signal, from which drift components are removed by the high pass filter 30, into a low impedance signal from a high impedance signal, and outputs the low impedance signal to the inverting amplifying portion 141. The inverting amplifying portion 141 inversion-amplifies the signal output from the voltage follower 142 with the gain (Roa/Ria), and outputs a resultant output signal Vout to the signal processing circuit 80D through an output terminal. The output signal Vout of the inverting amplifier 140 corresponds to a time-series signal of Voy1, Voy2, Vop1 and Vop2.

According to the modified example of the fourth embodiment, the same effect as that obtained in the fourth embodiment can be obtained. That is, since the signal Voy1 is in a differential relationship with the signal Voy2 about the reference potential Vr and the signal Vop1 is in a differential relationship with the signal Vop2 about the reference potential Vr, the difference between the two signals Voy1 and Voy2 and the difference between the two signals Vop1 and Vop2 are obtained, so that a dynamic range 2·Vd which is twice as wide as the dynamic range Vd of the basic amplification circuit is acquired. Further, the amplification circuit 20J has a gain equal to that of the basic amplification circuit, so that the angular velocity signals can be generated without reduction in the detection sensitivity.

### Fifth Embodiment

FIG. 13 is a circuit diagram illustrating the configuration of an amplification circuit of an angular velocity signal according to the fifth embodiment of the invention. In FIG. 13, the same reference numerals are used to designate the same elements as those of FIG. 11, and detailed description thereof will be omitted in order to avoid redundancy.

The amplification circuit 20E of the embodiment further includes a gain variable circuit 201 capable of variably setting the gain (the first gain) of the non-inverting amplifier 40a, in addition to the amplification circuit 20D shown in FIG. 11. The gain variable circuit 201 is configured to adjust the negative feedback resistors of the non-inverting amplifier 40a to variably set the gain (the first gain) of the non-inverting amplifier 40a.

The gain variable circuit 201 includes first negative feedback resistors 42a and 42b connected in parallel to each other, and second variable resistors 43a and 43b serially connected to each other. The resistors 42a, 42b, 43a and 43b have resistance values of Ria, Rib, Roa and Rob, respectively. The gain variable circuit 201 further includes a first switch 44 capable of invalidating a connection of the resistor 42b to the OP amp 41, and a second switch 45 capable of invalidating a connection of the resistor 43b to the OP amp 41. The first switch 44 is serially connected to the resistor 42b and the second switch 45 is connected in parallel to the resistor 43b. The first switch 44 has an on-resistance value much smaller than that of the resistor 42b, and the second switch 45 has an on-resistance value much smaller than that of the resistor 43b.

The first and second switches 44 and 45 are switched according to signal levels of switching signals S2 and S3. For example, the first switch 44 is turned on when the switching signal S2 is at a high level and is turned off when the switching signal S2 is at a low level. Similarly to this, the second switch 45 is turned on when the switching signal S3 is at a high level and is turned off when the switching signal S3 is at a low level. The switching signals S2 and S3 may be output from the signal processing circuit 80E. Alternatively, the switching signals S2 and S3 may be output from other control circuits. Further, the first and second switches 44 and 45 are configured in that their states are not changed if already set. However, the invention is not limited thereto. For example, the states of the first and second switches 44 and 45 may be appropriately changed during the operation of an electronic apparatus.

The resistance values Ria, Rib, Roa and Rob are not particularly limited. In other words, the resistance values can be set to appropriate values. For example, if (Ria=Rib=R/5) is established and (Roa=Rob=5R) is established, when all the switches 44 and 45 are turned on, the gain of the non-inverting amplifier 40a is 51 (times). Further, the gain when the first switch 44 is turned on and the second switch 45 is turned off is 101 (times), and the gain when the first switch 44 is turned off and the second switch 45 is turned on is 26 (times). In addition, the gain when all the switches 44 and 45 are turned off is 51 (times).

According to the amplification circuit 20E having the above configuration, since the gain of the non-inverting amplifier 40a can be optimized according to the processing capacity, device, specifications or purpose of the signal processing circuit 80E, it is advantageous in that a gain can be individually set for each device by using a common circuit structure. For example, it is possible to provide an amplification circuit capable of easily coping with each gain necessary for a different type of electronic apparatus such as a camera, a car navigation system or a game controller.

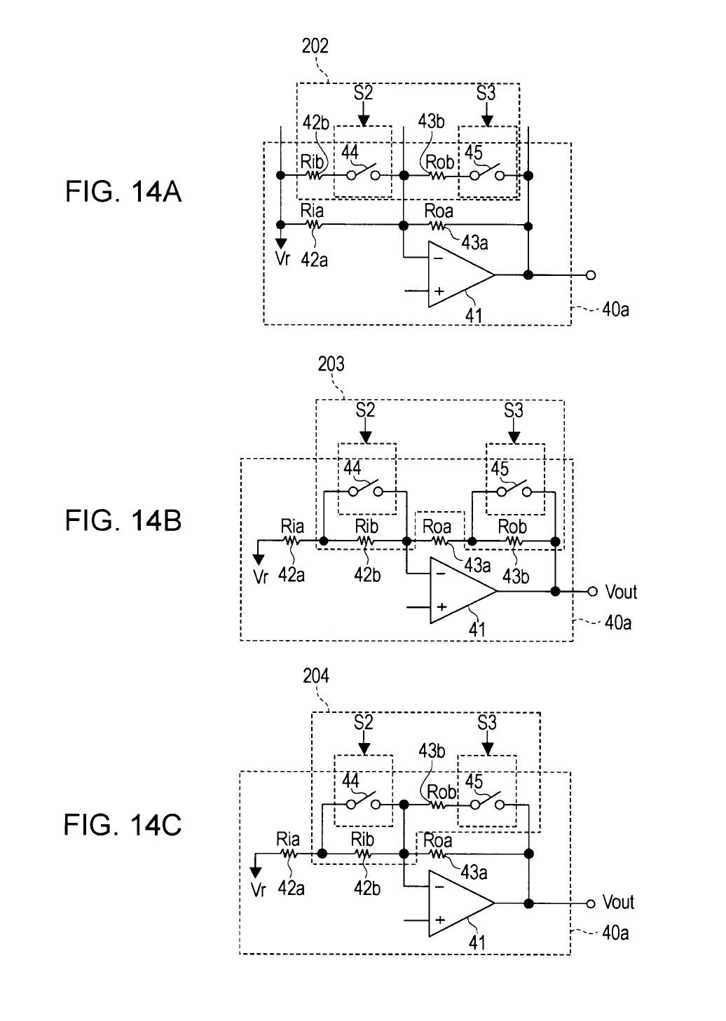

FIGS. 14A to 14C are circuit diagrams illustrating main elements according to modified examples of the configuration of the gain variable circuit. In FIGS. 14A to 14C, the same reference numerals are used to designate the same elements as those of FIG. 13, and detailed description thereof will be omitted in order to avoid redundancy.

A gain variable circuit 202 shown in FIG. 14A has a configuration example in which the resistors 42b and 43b are connected in parallel to the resistors 42a and 43a, respectively. In such a case, the switches 44 and 45 are serially connected to the resistors 42b and 43b, respectively. A gain variable circuit 203 shown in FIG. 14B has a configuration example in which the resistors 42b and 43b are serially connected to the resistors 42a and 43a, respectively. In such a case, the switches 44 and 45 are connected in parallel to the resistors 42b and 43b, respectively. A gain variable circuit 204 shown in FIG. 14C has a configuration example in which the resistor 42b is serially connected to the resistor 42a and the resistor 43b is connected in parallel to the resistor 43a. In such a case, the switch 44 is connected in parallel to the resistor 42b and the switch 45 is serially connected to the resistor 43a.

According to the configuration examples of FIGS. 14A to 14C, the same effect as that obtained in the above can be obtained. In addition, as shown in FIG. 13 and FIGS. 14A to 14C, the gain variable circuit includes the two switches 44 and 45. However, any one of the switches 44 and 45 may be omitted, or at least one of the resistors may be replaced with a variable resistor.

### Sixth Embodiment

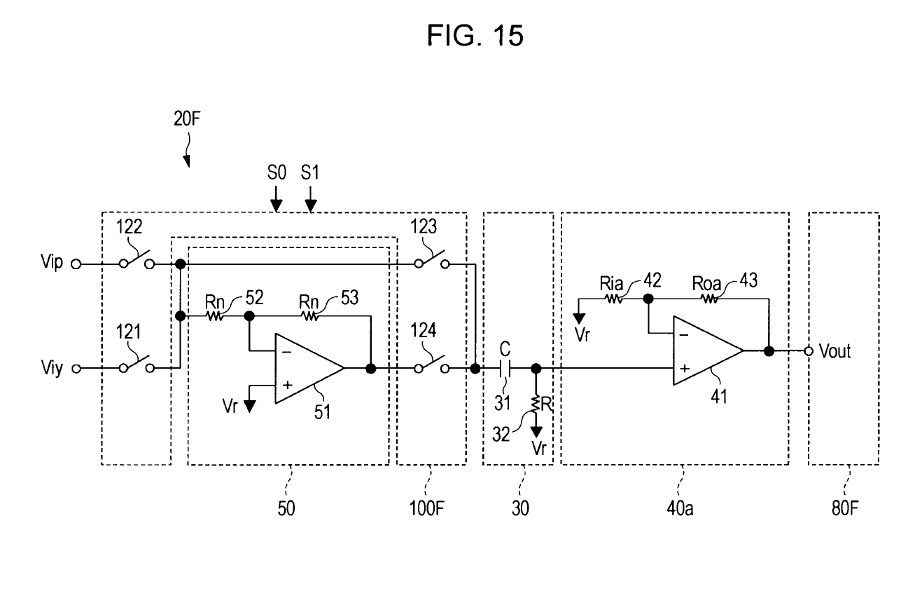

FIG. 15 is a circuit diagram illustrating the configuration of an amplification circuit of an angular velocity signal according to the sixth embodiment of the invention. In FIG. 15, the same reference numerals are used to designate the same elements as those of FIG. 6, and detailed description thereof will be omitted in order to avoid redundancy.

The amplification circuit 20F of the embodiment includes the non-inverting amplifier 40a (first amplification circuit section) and the inverting amplifier 50 (second amplification circuit section). A switch circuit 100F is provided at input and output sides of the inverting amplifier 50. Further, the high pass filter 30 is provided at an input side of the non-inverting amplifier 40a and a signal processing circuit 80F is provided at an output side of the non-inverting amplifier 40a.

The inverting amplifier 50 has the same configuration as that of the inverting amplifier 50 shown in FIG. 6. An output side of the inverting amplifier 50 is connected to the high pass filter 30 through the switch circuit 100F, and an output side of the high pass filter 30 is connected to the non-inverting input terminal (+) of the non-inverting amplifier 40a.

The sensor device 10y for detecting the angular velocity of the yaw direction outputs the detection signal Viy and the sensor device 10p for detecting the angular velocity of the pitch direction outputs the detection signal Vip. The detection signals Viy and Vip can be configured to be input to the high pass filter 30 through the switch circuit 100F. The high pass filter 30 removes drift components of the electrical signal corresponding to the angular velocity changing with respect to the reference potential Vr from various input signals output from the switch circuit 100F. The non-inverting amplifier 40a generates output signals Voy1 and Vop1 (first output signals) by non-inverting amplifying the detection signals Viy and Vip having passed through the high pass filter 30 with the first gain (first amplification circuit section).

Further, the detection signals Viy and Vip are input to an input terminal of the inverting amplifier 50 through the switch circuit 100F. The inverting amplifier 50 generates output signals Viy2 and Vip2 (third output signals) by inverting-amplifying the detection signals Viy and Vip with a gain having a value of 1. Then, the inverting amplifier 50 inputs the output signals Viy2 and Vip2 to the non-inverting amplifier 40a, thereby allowing output signals Voy2 and Vop2 (second output signals) to be generated by non-inverting amplifying the output signals with the gain having a value of 1 (second amplification circuit section). In the embodiment, the output signal Viy2 (fourth output signal) related to the detection signal Viy and the output signal Vip2 (fifth output signal) related to the detection signal Vip are generated by the single inverting amplifier 50. Input of the detection signals Viy and Vip to the inverting amplifier 50 is controlled by the switch circuit 100F.

The switch circuit 100F includes four switch sections 121 to 124. The switch sections 121 and 123 switch the input and cutoff of the detection signal Viy to the non-inverting amplifier 40a and the inverting amplifier 50. The switch sections 122 and 123 switch the input and cutoff of the detection signal Vip to the non-inverting amplifier 40a and the inverting amplifier 50. The switch section 124 switches the input and cutoff of the output signals Viy2 and Vip2 to the non-inverting amplifier 40a.

The switch sections (bilateral switches) 121 to 124 are switched by the select signals S0 and S1 which are input to the switch circuit 100F from the signal processing circuit 80F. The select signals S0 and S1 each are at a high level and a low level, and a switch section to be turned on is determined by the combination of these signal levels. When two switch sections are turned on, the remaining two switch sections are turned off.

In the embodiment, when all the signals S0 and S1 are at a low level, the switch sections 121 and 123 are turned on. When all the signals S0 and S1 are at a high level, the switch sections 122 and 124 are turned on. Further, when the signal S0 is at a low level and the signal S1 is at a high level, the switch sections 121 and 124 are turned on. When the signal S0 is at a high level and the signal S1 is at a low level, the switch sections 122 and 123 are turned on.

The switch circuit 100F selectively switches a first state in which the first output signal Voy1 or Vop1 is input to the signal processing circuit 80F, and a second state in which the second output signals Voy2 or Vop2 are input to the signal processing circuit 80F. According to the embodiment, the first state is classified into a first switching state in which the first output signal Voy1 is input to the signal processing circuit 80F, and a second switching state in which the first output signal Vop1 is input to the signal processing circuit 80F. Meanwhile, the second state is classified into a third switching state in which the second output signal Voy2 is input to the signal processing circuit 80F, and a fourth switching state in which the second output signal Vop2 is input to the signal processing circuit 80F.

Thus, in the amplification circuit 20F shown in FIG. 15, the first switching state is established when the switch sections 121 and 123 are turned on and the second switching state is established when the switch sections 122 and 123 are turned on. Further, the third switching state is established when the switch sections 121 and 124 are turned on and the fourth switching state is established when the switch sections 122 and 124 are turned on. In such a case, the switch sections 121 to 123 correspond to a first switch circuit section capable of limiting the input of the detection signals Viy and Vip to the first amplification circuit section (the non-inverting amplifier 40a). Further, the switch section 124 corresponds to a second switch circuit section capable of limiting the input of the third output signals (fourth output signal Viy2 and fifth output signal Vip2) to the first amplification circuit section (the non-inverting amplifier 40a).

The signal processing circuit 80F includes a signal generator for generating the select signals S0 and S1 input to the switch circuit 100F, and a memory enough to store the signals output from the non-inverting amplifier 40a. Further, the signal processing circuit 80F calculates the difference between the first output signals (Voy1, Vop1) and the second output signals (Voy2, Vop2), which are output from the non-inverting amplifier 40a, thereby generating angular velocity signals. That is, the signal processing circuit 80F calculates the difference between Voy1 and Voy2 to generate the angular velocity signal of the yaw direction, and calculates the difference between Vop1 and Vop2 to generate the angular velocity signal of the pitch direction.

In the amplification circuit 20F having the configuration as described above according to the embodiment, the switch circuit 100F sequentially switches the switch sections 121 to 124 based on the select signals S0 and S1 provided from the signal processing circuit 80F, so that the signals Viy, Viy2, Vip and Vip2 are converted into time-series signals and input to the high pass filter 30 and the non-inverting amplifier 40a. When the detection signal Viy is input, the inverting amplifier 50 inversion-amplifies the detection signal Viy with a gain having a value of 1 to generate the fourth output signal Viy2. When the detection signal Vip is input, the inverting amplifier 50 inversion-amplifies the detection signal Vip with the gain having a value of 1 to generate the fifth output signal Vip2.

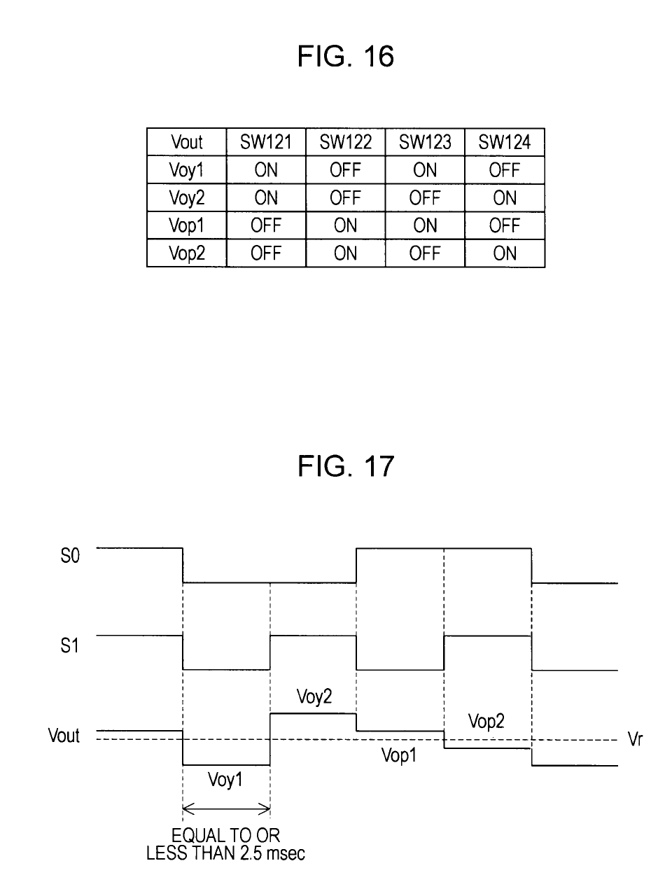

The non-inverting amplifier 40a amplifies an input signal, which is obtained by removing drift components of the electrical signal corresponding to the angular velocity changing with respect to the reference potential Vr by using the high pass filter 30, with the first gain (1+(Roa/Ria)), and inputs a resultant output signal Vout to the signal processing circuit 80F. The output signal Vout of the non-inverting amplifier 40a corresponds to a time-series signal of Voy1, Voy2, Vop1 and Vop2. FIG. 16 is a table illustrating the relationship between the on and off state of the switch sections 121 to 124 and the output signals. FIG. 17 is a diagram illustrating one example of variation of the signal levels of the select signals S0 and S1 with respect to time and variation of the output signal Vout of the non-inverting amplifier 40a with respect to time. In the example of FIG. 17, the non-inverting amplifier 40a generates the output signals in the sequence of Voy1, Voy2, Vop1 and Vop2. Further, the embodiment describes an example in which the angular velocity of the yaw direction is larger than the angular velocity of the pitch direction. However, the invention is not limited thereto.

The signal processing circuit 80F sequentially receives the output signals from the non-inverting amplifier 40a, and calculates a differential signal between Voy1 and Voy2 and a differential signal between Vop1 and Vop2, thereby generating angular velocity signals of the yaw direction and the pitch direction, respectively. Since the output signal Voy1 is in a differential relationship with the output signal Voy2 about the reference potential Vr and the output signal Vop1 is in a differential relationship with the output signal Vop2 about the reference potential Vr, the difference between the two signals Voy1 and Voy2 and the difference between the two signals Vop1 and Vop2 are obtained, so that a dynamic range 2·Vd which is twice as wide as the dynamic range Vd of the basic amplification circuit is acquired. Further, the amplification circuit 20F of the embodiment has a gain equal to that of the basic amplification circuit, so that the angular velocity signals can be generated without reduction in the detection sensitivity.

Further, according to the embodiment, the single non-inverting amplifier 40a and the single inverting amplifier 50 can perform an amplification process with respect to the detection signals of the yaw direction and the pitch direction, resulting in the reduction of the number of parts. In addition, it is advantageous in that the number of the switch sections of the switch circuit can be reduced as compared with the amplification circuit 20D shown in FIG. 11. Moreover, since the output signals Voy1, Voy2, Vop1 and Vop2 are input to the signal processing circuit 80F in time-series, it is advantageous in that one input terminal and one A/D converter is necessary for the signal processing circuit 80F.

In the embodiment, a switching frequency of the first to fourth switching states of the switch circuit 100F is set to 400 Hz or more. Consequently, the angular velocities of the yaw direction and the pitch direction can be detected with high accuracy. Further, the switching frequency is set such that each switching state is continued for 1 msec or less, thereby effectively preventing the generation of a photograph blurred by shaking.

[Modified Example of Sixth Embodiment]

Next, the modified example of the sixth embodiment will be described. In the modified example of the sixth embodiment, a case in which an amplification circuit includes the combination of an inverting amplifier and another inverting amplifier will be described.

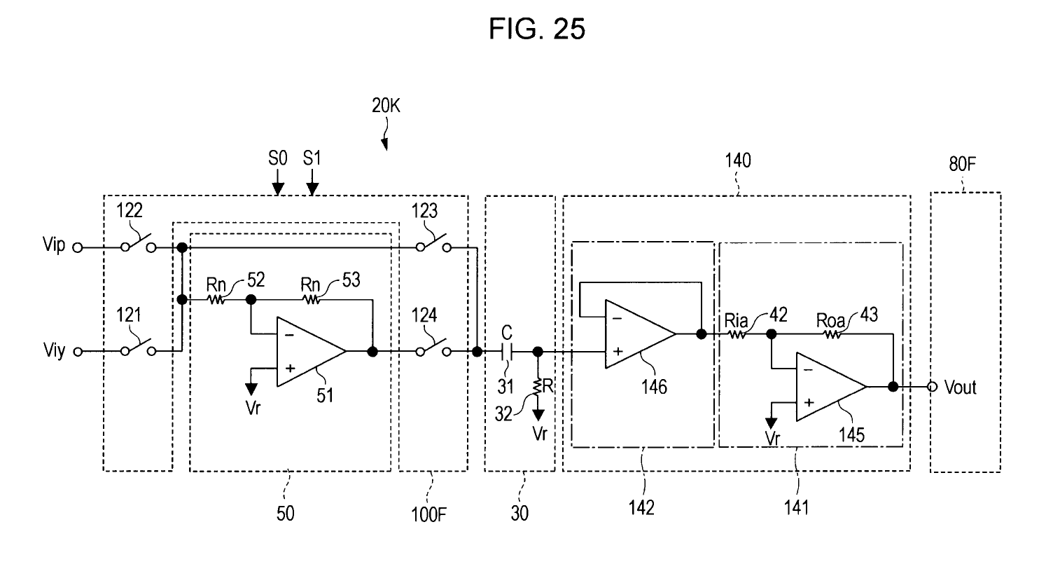

FIG. 25 is a circuit diagram illustrating one example in which the amplification circuit includes the combination of an inverting amplifier and another inverting amplifier.

As shown in FIG. 25, in the amplification circuit 20K according to the modified example, the non-inverting amplifier 40a shown in FIG. 15 is replaced with an inverting amplifier 140.

The inverting amplifier 140 includes the inverting amplifying portion 141 having the OP amp 145, the first negative feedback resistor 42 and the second negative feedback resistor 43, and the voltage follower 142 having the OP amp 146.

The switch circuit 100F sequentially switches the switch sections 121 to 124 based on the select signals S0 and S1 provided from the signal processing circuit 80F, so that the signals Viy, Viy2, Vip and Vip2 are converted into time-series signals and input to the high pass filter 30 and the inverting amplifier 140. When the detection signal Viy is input, the inverting amplifier 50 inversion-amplifies the detection signal Viy with a gain having a value of 1 to generate the output signal Viy2. When the detection signal Vip is input, the inverting amplifier 50 inversion-amplifies the detection signal Vip with the gain having a value of 1 to generate the output signal Vip2.

The voltage follower 142 of the inverting amplifier 140 converts an input signal, from which drift components are removed by the high pass filter 30, into a low impedance signal from a high impedance signal, and outputs the low impedance signal to the inverting amplifying portion 141. The inverting amplifying portion 141 inversion-amplifies the signal output from the voltage follower 142 with the gain (Roa/Ria), and outputs a resultant output signal Vout to the signal processing circuit 80F through an output terminal. The output signal Vout of the inverting amplifier 140 corresponds to a time-series signal of Voy1, Voy2, Vop1 and Vop2.

According to the modified example of the sixth embodiment, the same effect as that obtained in the sixth embodiment can be obtained. That is, since the output signal Voy1 is in a differential relationship with the output signal Voy2 about the reference potential Vr and the output signal Vop1 is in a differential relationship with the output signal Vop2 about the reference potential Vr, the difference between the two signals Voy1 and Voy2 and the difference between the two signals Vop1 and Vop2 are obtained, so that a dynamic range 2·Vd which is twice as wide as the dynamic range Vd of the basic amplification circuit is acquired. Further, the amplification circuit 20K has a gain equal to that of the basic amplification circuit, so that the angular velocity signals can be generated without reduction in the detection sensitivity.

### Seventh Embodiment

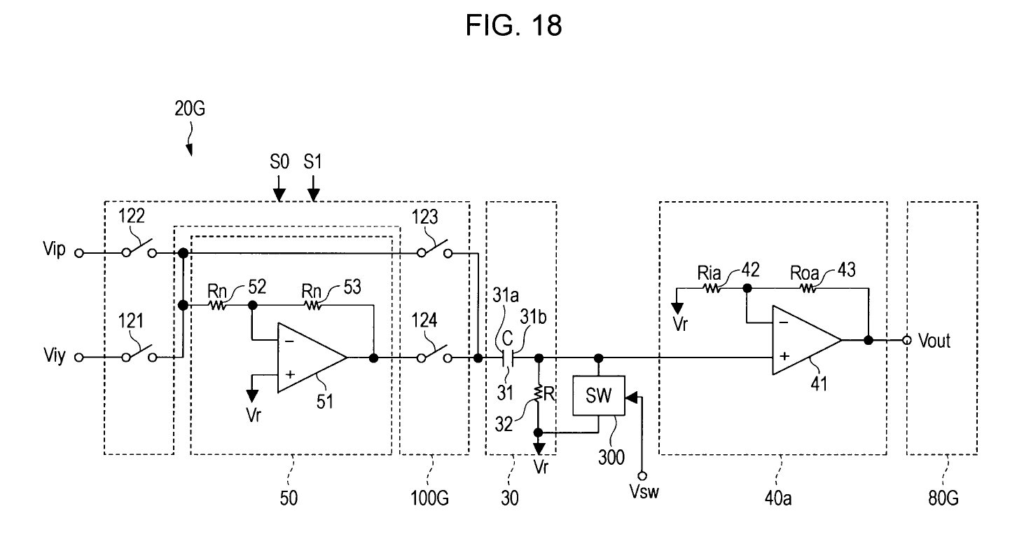

FIG. 18 is a circuit diagram illustrating the configuration of an amplification circuit of an angular velocity signal according to the seventh embodiment of the invention. In FIG. 18, the same reference numerals are used to designate the same elements as those of FIG. 15, and detailed description thereof will be omitted in order to avoid redundancy.

In order that an appropriate amplification process is performed with respect to an input signal by the non-inverting amplifier 40a while band limitation is being performed with respect to the input signal by the high pass filter 30, it is preferred that the potential difference between an input-side electrode 31a and an output-side electrode 31b of the capacitor 31 is basically set to 0V. Thus, the output-side electrode 31b of the capacitor 31 is connected to the reference potential Vr through the resistor 32, so that the electrode 31b can be charged and discharged. However, since a time constant decided by the product of a capacitance C of the capacitor 31 and a resistance value R of the resistor 32 is large, time is necessary when the electrode 31b is charged and discharged. In addition, the electrode 31b may not be appropriately charged and discharged according to the magnitude of an angular velocity acting on the casing 2. If the electrode 31b is not appropriately charged and discharged, a potential difference may occur between both electrodes of the capacitor 31, resulting in the saturation of an output voltage of the non-inverting amplifier 40a.

In this regard, an amplification circuit 20G according to the embodiment further includes a switch mechanism 300 for charging and discharging the high pass filter 30 as compared with the amplification circuit 20F shown in FIG. 15. The switch mechanism 300 bypasses the resistor 32 of the high pass filter 30 based on a driving signal Vsw to achieve a connection between the output-side electrode 31b of the capacitor 31 and the reference potential Vr. For example, the driving signal Vsw is generated by a signal processing circuit 80G and output therefrom. However, the driving signal Vsw may also be generated by other control circuits.

An on-resistance value of the switch mechanism 300 is set to be lower than the time constant (C·R) of the high pass filter 30. For example, when C=22 μF and R=470 kΩ, since the time constant (C·R) is equal to 10.3 seconds, the resistance value (e.g., 200Ω) is set such that a time constant shorter than 10. 3 seconds is obtained. Consequently, a rapid charge and discharge function of the capacitor 31 can be obtained, so that an appropriate amplification process can be performed with respect to the detection signal.

Further, in the amplification circuit 20G according to the embodiment, the capacitor 31 is charged and discharged by the switch mechanism 300, switch sections 121 to 123 of a switch circuit 100G are turned off and a switch section 124 is turned on. The switch sections 121 to 123 are turned off, so that the input signals Viy, Viy2, Vip and Vip2 can be prevented from being input to the high pass filter 30 when the capacitor 31 is charged and discharged. Further, the switch section 124 is turned on, so that an input potential corresponding to the reference potential Vr can be input to the high pass filter 30 from the inverting amplifier 50. Consequently, the input-side electrode 31a and the output-side electrode 31b of the capacitor 31 can be adjusted to match the reference potential, so that the potential difference between electrodes 31a and 31b can be set to 0.

As described above, the amplification circuit 20G according to the embodiment includes the switch mechanism capable of rapidly charging and discharging the capacitor 31 when the input of the detection signals to the non-inverting amplifier 40a is limited by the switch sections 121 to 123. Consequently, an appropriate operation of the high pass filter 30 can be ensured regardless of the influence of the magnitude of the angular velocity acting on the casing 2. The switch mechanism 300 can be likewise applied to the amplification circuits shown in FIGS. 9, 11, 13 and 15.

The amplification circuit may include the combination of an inverting amplifier and another inverting amplifier.

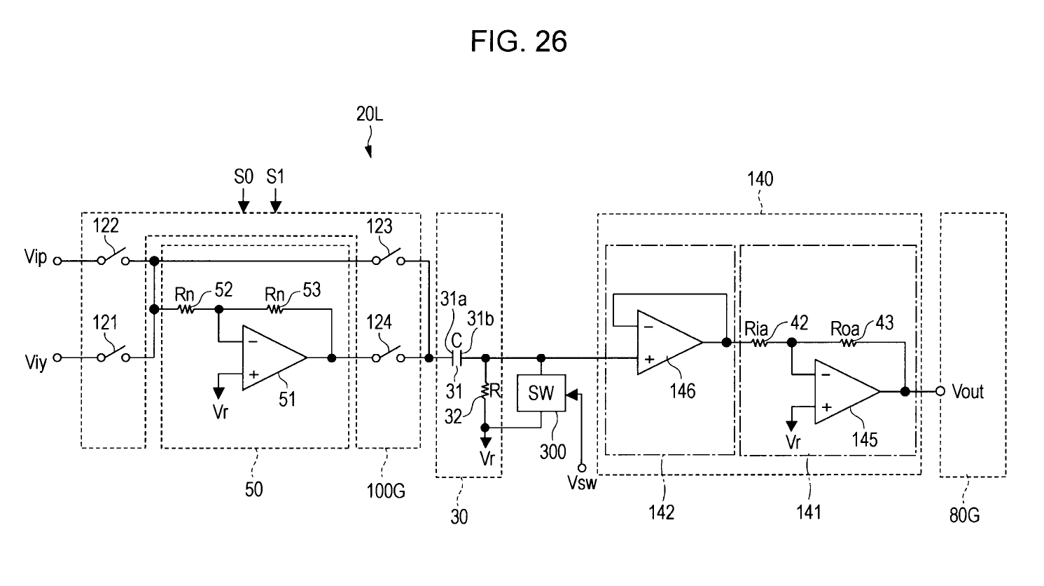

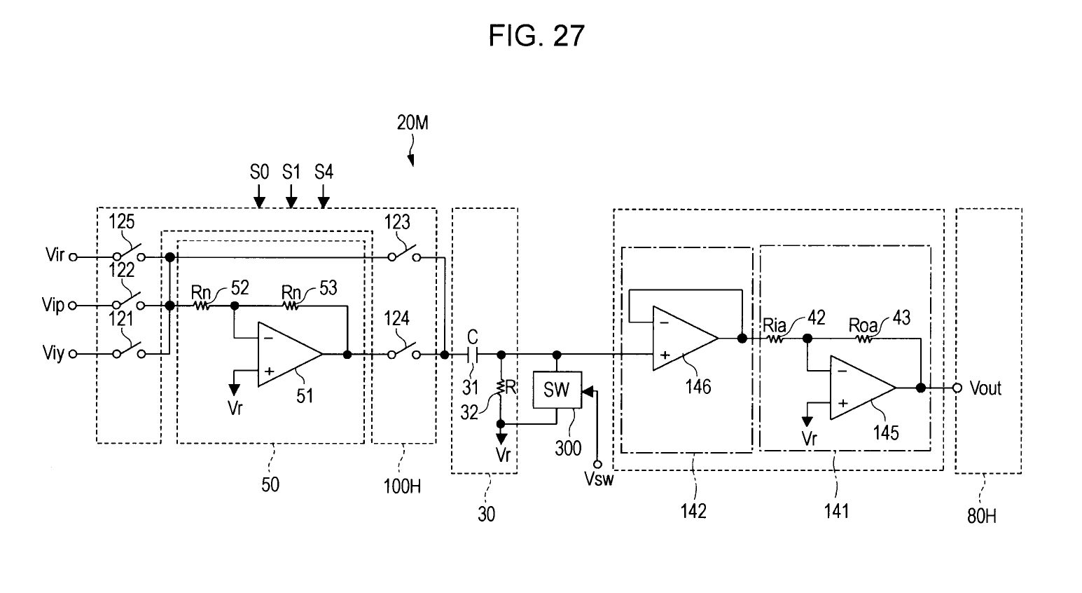

FIG. 26 is a circuit diagram illustrating one example in which the amplification circuit includes the combination of an inverting amplifier and another inverting amplifier.

In the amplification circuit 20L shown in FIG. 26, the non-inverting amplifier 40a shown in FIG. 18 is replaced with the inverting amplifier 140.

Even in such an example, the same effect as that obtained in the embodiment shown in FIG. 18 can be obtained.

### Eighth Embodiment

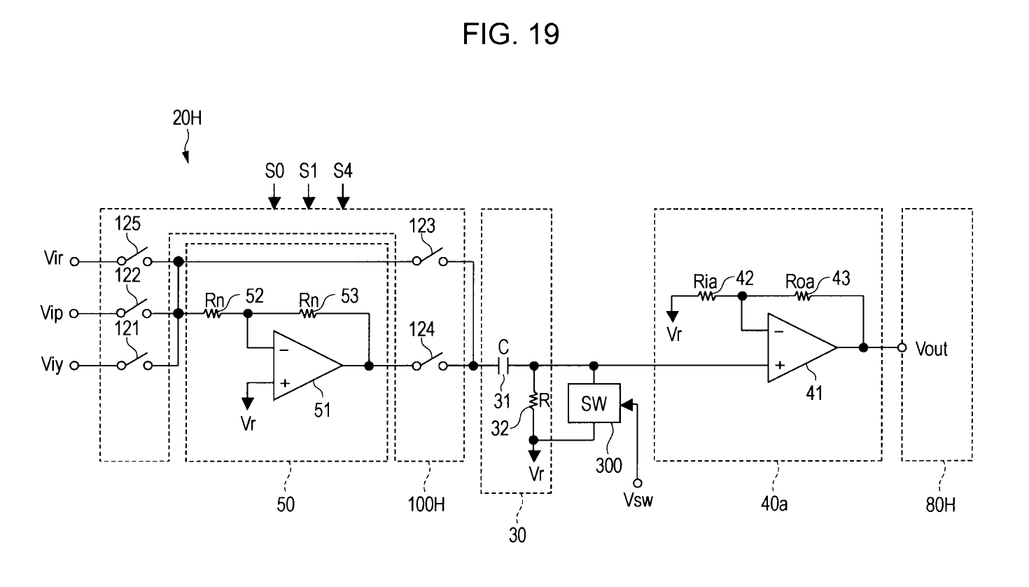

FIG. 19 is a circuit diagram illustrating the configuration of an amplification circuit of an angular velocity signal according to the eighth embodiment of the invention. In FIG. 19, the same reference numerals are used to designate the same elements as those of FIG. 18, and detailed description thereof will be omitted in order to avoid redundancy.

The amplification circuit 20H of the embodiment has a circuit configuration capable of performing angular velocity detection of the yaw direction, the pitch direction and the roll direction. Input signals Viy, Vip and Vir represent angular velocity detection signals of the yaw direction, the pitch direction and the roll direction, respectively. The detection signals Viy, Vip and Vir are configured to be input to the high pass filter 30 through a switch circuit 100H. The non-inverting amplifier 40a generates output signals Voy1, Vop1 and Vor1 (first output signals) by non-inverting amplifying the detection signals Viy, Vip and Vir having passed through the high pass filter 30 with the first gain (first amplification circuit section).

Further, the detection signals Viy, Vip and Vir are input to an input terminal of the inverting amplifier 50 through the switch circuit 100H. The inverting amplifier 50 generates output signals Viy2, Vip2 and Vir2 (third output signals) by inverting-amplifying the detection signals Viy, Vip and Vir with a gain having a value of 1. Then, the inverting amplifier 50 inputs the output signals Viy2, Vip2 and Vir2 to the non-inverting amplifier 40a, thereby allowing output signals Voy2, Vop2 and Vor2 (second output signals) to be generated by non-inverting amplifying the output signals with the gain having a value of 1 (second amplification circuit section). In the embodiment, the output signal Viy2 (fourth output signal) related to the detection signal Viy, the output signal Vip2 (fifth output signal) related to the detection signal Vip, and the output signal Vir2 (sixth output signal) related to the detection signal Vir are generated by the single inverting amplifier 50. Input of the detection signals Viy, Vip and Vir to the inverting amplifier 50 is controlled by the switch circuit 100H.

The switch circuit 100H includes five switch sections 121 to 125. The switch sections 121 and 123 switch the input and cutoff of the detection signal Viy to the non-inverting amplifier 40a and the inverting amplifier 50. The switch sections 122 and 123 switch the input and cutoff of the detection signal Vip to the non-inverting amplifier 40a and the inverting amplifier 50. The switch section 124 switches the input and cutoff of the output signals Viy2 and Vip2 to the non-inverting amplifier 40a. The switch sections 125 and 123 switch the input and cutoff of the detection signal Vir to the non-inverting amplifier 40a and the inverting amplifier 50.

The switch sections (bilateral switches) 121 to 125 are switched by select signals S0, S1 and S4 which are input to the switch circuit 100H from the signal processing circuit 80H. The select signals S0, S1 and S4 each are at a high level and a low level, and a switch section to be turned on is determined by the combination of these signal levels. When two switch sections are turned on, the remaining three switch sections are turned off.

In the embodiment, when all the signals S0, S1 and S4 are at a low level, the switch sections 121 and 123 are turned on. When only the signal S1 is at a high level, the switch sections 122 and 124 are turned on. Further, when only the signal S0 is at a high level, the switch sections 122 and 123 are turned on. When only the signal S4 is at a low level, the switch sections 122 and 124 are turned on. In addition, when only the signal S4 is at a high level, the switch sections 123 and 125 are turned on. When only the signal S0 is at a low level, the switch sections 124 and 125 are turned on.

The switch circuit 100H selectively switches a first state in which the first output signal Voy1, Vop1 or Vor1 is input to the signal processing circuit 80H, and a second state in which the second output signals Voy2, Vop2 or Vor2 is input to the signal processing circuit 80H. According to the embodiment, the first state is classified into a first switching state in which the first output signal Voy1 is input to the signal processing circuit 80H, a second switching state in which the first output signal Vop1 is input to the signal processing circuit 80H, and a fifth switching state in which the first output signal Vor1 is input to the signal processing circuit 80H. Meanwhile, the second state is classified into a third switching state in which the second output signal Voy2 is input to the signal processing circuit 80H, a fourth switching state in which the second output signal Vop2 is input to the signal processing circuit 80H, and a sixth switching state in which the second output signal Vor2 is input to the signal processing circuit 80H.

Thus, in the amplification circuit 20H shown in FIG. 19, the first switching state is established when the switch sections 121 and 123 are turned on and the second switching state is established when the switch sections 122 and 123 are turned on. Further, the third switching state is established when the switch sections 121 and 124 are turned on and the fourth switching state is established when the switch sections 122 and 124 are turned on. In addition, the fifth switching state is established when the switch sections 123 and 125 are turned on and the sixth switching state is established when the switch sections 124 and 125 are turned on. In such a case, the switch sections 121 to 123 and 125 correspond to a first switch circuit section capable of limiting the input of the detection signals Viy, Vip and Vir to the first amplification circuit section (the non-inverting amplifier 40a). Further, the switch section 124 corresponds to a second switch circuit section capable of limiting the input of the third output signals (fourth output signal Viy2, fifth output signal Vip2 and sixth output signal Vir2) to the first amplification circuit section (the non-inverting amplifier 40a).

The signal processing circuit 80H includes a signal generator for generating the select signals S0, S1 and S4 input to the switch circuit 100H, and a memory enough to store the signals output from the non-inverting amplifier 40a. Further, the signal processing circuit 80H calculates the difference between the first output signals (Voy1, Vop1, Vor1) and the second output signals (Voy2, Vop2, Vor2), which are output from the non-inverting amplifier 40a, thereby generating angular velocity signals. That is, the signal processing circuit 80H calculates the difference between Voy1 and Voy2 to generate the angular velocity signal of the yaw direction, and calculates the difference between Vop1 and Vop2 to generate the angular velocity signal of the pitch direction. Further, the signal processing circuit 80H calculates the difference between Vor1 and Vor2 to generate the angular velocity signal of the roll direction.

In the amplification circuit 20H having the configuration as described above according to the embodiment, the switch circuit 100H sequentially switches the switch sections 121 to 125 based on the select signals S0, S1 and S4 provided from the signal processing circuit 80H, so that the signals Viy, Viy2, Vip, Vip2, Vir and Vir2 are converted into time-series signals and input to the high pass filter 30 and the non-inverting amplifier 40a. When the detection signal Viy is input, the inverting amplifier 50 inversion-amplifies the detection signal Viy with a gain having a value of 1 to generate the fourth output signal Viy2. When the detection signal Vip is input, the inverting amplifier 50 inversion-amplifies the detection signal Vip with the gain having a value of 1 to generate the fifth output signal Vip2. Further, when the detection signal Vir is input, the inverting amplifier 50 inversion-amplifies the detection signal Vir with the gain having a value of 1 to generate the sixth output signal Vir2.

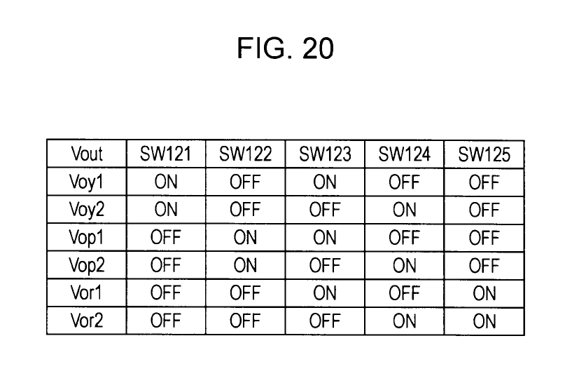

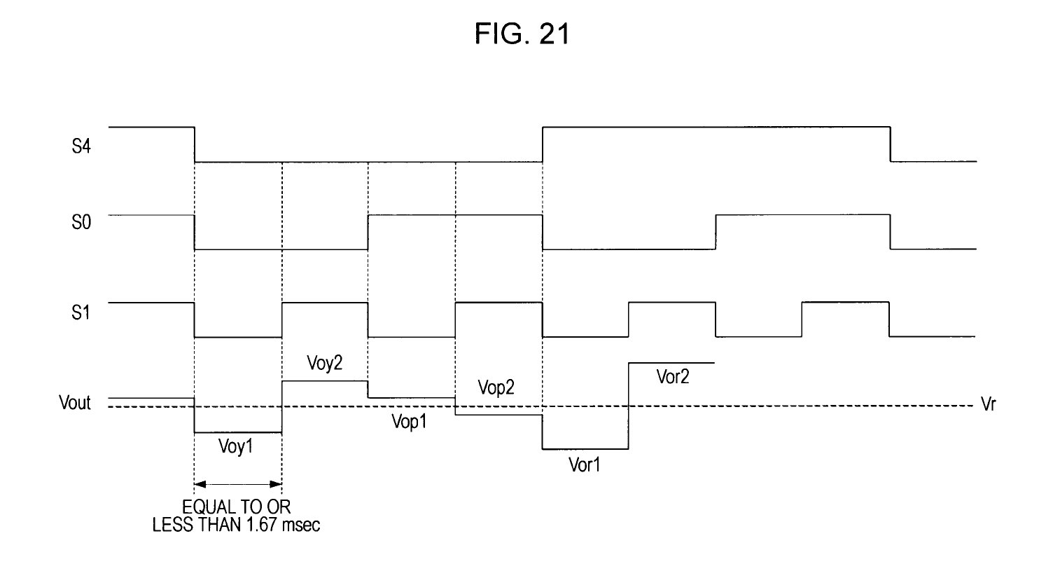

The non-inverting amplifier 40a amplifies an input signal, which is obtained by removing drift components of the electrical signal corresponding to the angular velocity changing with respect to the reference potential Vr by using the high pass filter 30, with the first gain (1+(Roa/Ria)), and inputs a resultant output signal Vout to the signal processing circuit 80H. The output signal Vout of the non-inverting amplifier 40a corresponds to a time-series signal of Voy1, Voy2, Vop1, Vop2, Vor1 and Vor2. FIG. 20 is a table illustrating the relationship between the on and off state of the switch sections 121 to 125 and the output signals. FIG. 21 is a diagram illustrating one example of variation of the signal levels of the select signals S0, S1 and S4 with respect to time and variation of the output signal Vout of the non-inverting amplifier 40a with respect to time. In the example of FIG. 21, the non-inverting amplifier 40a generates the output signals in the sequence of Voy1, Voy2, Vop1, Vop2, Vor1 and Vor2. Further, the embodiment describes an example in which the angular velocity of the yaw direction is larger than the angular velocity of the pitch direction and the angular velocity of the roll direction is larger than the angular velocity of the yaw direction. However, the invention is not limited thereto.

The signal processing circuit 80H sequentially receives the output signals from the non-inverting amplifier 40a, and calculates a differential signal between Voy1 and Voy2, a differential signal between Vop1 and Vop2 and a differential signal between Vor1 and Vor2, thereby generating angular velocity signals of the yaw direction, the pitch direction and the roll direction, respectively. Since the output signal Voy1 is in a differential relationship with the output signal Voy2 about the reference potential Vr, the output signal Vop1 is in a differential relationship with the output signal Vop2 about the reference potential Vr and the output signal Vor1 is in a differential relationship with the output signal Vor2 about the reference potential Vr the difference between the two signals Voy1 and Voy2, the difference between the two signals Vop1 and Vop2 and the difference between the two signals Vor1 and Vor2 are obtained, so that a dynamic range 2·Vd which is twice as wide as the dynamic range Vd of the basic amplification circuit is acquired. Further, the amplification circuit 20H of the embodiment has a gain equal to that of the basic amplification circuit, so that the angular velocity signals can be generated without reduction in the detection sensitivity.

Further, according to the embodiment, the single non-inverting amplifier 40a and the single inverting amplifier 50 can perform an amplification process with respect to the detection signals of the yaw direction, the pitch direction and the roll direction, resulting in the reduction of the number of parts. In addition, since the output signals Voy1, Voy2, Vop1, Vop2, Vor1 and Vor2 are input to the signal processing circuit 80H in time-series, it is advantageous in that one input terminal and one A/D converter is necessary for the signal processing circuit 80H.

In the embodiment, a switching frequency of the first to sixth switching states made by the switching sections 121 to 125 of the switch circuit 100H is set to 600 Hz or more. Since a detection frequency of the angular velocities of the yaw direction, the pitch direction and the roll direction is equal to or less than 100 Hz (10 msec), the switching frequency of the switching states is set to be equal to or more than 600 Hz (switching time is equal to or less than 1.67 msec), so that the angular velocity of each direction can be detected with high accuracy at a frequency of 100 Hz or less. In general, as the shutter speed of a camera is slow (exposure time is long), a photograph blurred by shaking may be easily generated. In this regard, in order to effectively prevent the generation of the photograph blurred by shaking, it is preferred to increase the shutter speed. For example, the shutter speed may be set to 4 msec or less. In such a case, the switching frequency is set such that each switching state is continued for 0.67 msec or less, thereby effectively preventing the generation of the photograph blurred by shaking. The lower limit of the switching time is not particularly limited. It is preferred to cope with a maximum shutter speed of a camera used. For example, when the maximum shutter speed is 0.125 msec, the switching time of each switching state is 20.8 μsec.

The amplification circuit may include the combination of an inverting amplifier and another inverting amplifier.

FIG. 27 is a circuit diagram illustrating one example in which the amplification circuit includes the combination of an inverting amplifier and another inverting amplifier.

In the amplification circuit 20M shown in FIG. 27, the non-inverting amplifier 40a shown in FIG. 19 is replaced with the inverting amplifier 140.

Even in such an example, the same effect as that obtained in the embodiment shown in FIG. 19 can be obtained.

### Various Modified Examples

Up to now, the embodiments of the invention have been described. However, the invention is not limited thereto, and various modified examples can be made based on the technical scope of the invention.

For example, in the previous embodiments, the amplification circuits of the angular velocity signal for shake correction have been described as examples. However, the invention is not limited thereto. For example, the invention can also be applied to an input device such as a game controller that detects variation of the posture of the casing to control an image displayed on a display.

Further, differently from the amplification circuits of the previous embodiments, it may be possible to switch a first mode in which an angular velocity is detected in a normal dynamic range, and a second mode in which an angular velocity is detected in a dynamic range which is twice as wide as the normal dynamic range. In such a case, when a high angular velocity is applied to the casing, the first mode may be switched into the second mode to detect the angular velocity.

In FIGS. 23 to 27, the cases in which each amplification circuit includes the combination of an inverting amplifier and another inverting amplifier have been described by making them correspond to FIGS. 6, 11, 15, 18 and 19. However, examples in which the amplification circuit includes the combination of an inverting amplifier and another inverting amplifier are not limited thereto. For example, in the embodiments described in FIGS. 8, 9, 13 and the like, the amplification circuit may include the combination of an inverting amplifier and another inverting amplifier.

The present application contains subject matter related to that disclosed in Japanese Priority Patent Application JP 2009-130137 filed in the Japan Patent Office on May 29, 2009, and Japanese Priority Patent Application JP 2010-005632 filed in the Japan Patent Office on Jan. 14, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An angular velocity sensor comprising:
a sensor device that generates a detection signal corresponding to an angular velocity; and
an amplification circuit that generates both a first output signal by non-inverting amplifying the detection signal with a first gain and a second output signal by inverting-amplifying the detection signal with the first gain, and outputs the first output signal and the second output signal in order to obtain an angular velocity signal by calculating a difference between the first output signal and the second output signal.

2. The angular velocity sensor according to claim 1, further comprising a switch circuit that selectively switches a first state in which the first output signal is output from the amplification circuit, and a second state in which the second output signal is output from the amplification circuit.

3. The angular velocity sensor according to claim 2, wherein the amplification circuit includes:
a first amplification circuit section that generates the first output signal by non-inverting amplifying the detection signal with the first gain and outputs the first output signal; and
a second amplification circuit section that generates a third output signal by inverting-amplifying the detection signal with a second gain with a value of 1, and inputs the third output signal to the first amplification circuit section so that the second output signal is output from the first amplification circuit section,
wherein the switch circuit includes:
a first switch circuit section capable of limiting input of the detection signal to the first amplification circuit section; and
a second switch circuit section capable of limiting input of the third output signal to the first amplification circuit section.

4. The angular velocity sensor according to claim 2, wherein the amplification circuit includes:
a first amplification circuit section that generates the second output signal by inverting-amplifying the detection signal with the first gain and outputs the second output signal; and
a second amplification circuit section that generates a third output signal by inverting-amplifying the detection signal with a second gain with a value of 1, and inputs the third output signal to the first amplification circuit section so that the first output signal is output from the first amplification circuit section,
wherein the switch circuit includes:
a first switch circuit section capable of limiting input of the detection signal to the first amplification circuit section; and
a second switch circuit section capable of limiting input of the third output signal to the first amplification circuit section.

5. The angular velocity sensor according to claim 3, wherein the sensor device includes:
a first sensor device section that generates a first detection signal corresponding to an angular velocity about a first axis along a first direction as the detection signal; and
a second sensor device section that generates a second detection signal corresponding to an angular velocity about a second axis along a second direction different from the first direction as the detection signal,
wherein the first state is classified into a first switching state in which the first output signal related to the first detection signal is output from the amplification circuit, and a second switching state in which the first output signal related to the second detection signal is output from the amplification circuit, and the second state is classified into a third switching state in which the second output signal related to the first detection signal is output from the amplification circuit, and a fourth switching state in which the second output signal related to the second detection signal is output from the amplification circuit.

6. The angular velocity sensor according to claim 5, wherein the second amplification circuit section includes:
a first inverting amplifier that generates a fourth output signal as the third output signal by inverting-amplifying the first detection signal with the second gain; and
a second inverting amplifier that generates a fifth output signal as the third output signal by inverting-amplifying the second detection signal with the second gain,
wherein the first switch circuit section includes:
a first switch portion capable of limiting input of the first detection signal to the first amplification circuit section; and
a second switch portion capable of limiting input of the second detection signal to the first amplification circuit section, and
wherein the second switch circuit section includes:
a third switch portion capable of limiting input of the fourth output signal to the first amplification circuit section; and
a fourth switch portion capable of limiting input of the fifth output signal to the first amplification circuit section.

7. The angular velocity sensor according to claim 5, wherein the second amplification circuit section generates the third output signal by inverting-amplifying the first detection signal with the second gain when the first detection signal is received, and generates the third output signal by inverting-amplifying the second detection signal with the second gain when the second detection signal is received, and
the first switch circuit section includes:
a first switch portion capable of limiting input of the first detection signal to the first amplification circuit section;
a second switch portion capable of limiting input of the second detection signal to the first amplification circuit section;
a fifth switch portion capable of limiting input of the first detection signal to the second amplification circuit section; and
a sixth switch portion capable of limiting input of the second detection signal to the second amplification circuit section.

8. The angular velocity sensor according to claim 5, wherein the first to fourth switching states are sequentially switched by the switch circuit in a predetermined order, and a switch frequency of each switching state is equal to or more than 400 Hz.

9. The angular velocity sensor according to claim 3, further comprising a high pass filter provided between the first amplification circuit section and the second amplification circuit section to remove drift components from the detection signal.

10. The angular velocity sensor according to claim 9, wherein the high pass filter includes:
a capacitor having a first electrode connected to an input side of the first amplification circuit section and a second electrode connected to an output side of the second amplification circuit section; and
a resistor connected between the first electrode and a reference potential, and
wherein the angular velocity sensor further comprises a switch mechanism that bypasses the resistor to achieve a connection between the first electrode and the reference potential when the first switch circuit section limits the input of the detection signal to the first amplification circuit section.

11. The angular velocity sensor according to claim 1, wherein the amplification circuit includes:
a first amplification circuit section that generates the first output signal by non-inverting amplifying the detection signal with the first gain and outputs the first output signal; and
a second amplification circuit section that generates the second output signal by inverting-amplifying the first output signal with a second gain with a value of 1, and outputs the second output signal.

12. The angular velocity sensor according to claim 1, wherein the amplification circuit includes:
a first amplification circuit section that generates the second output signal by inverting-amplifying the detection signal with the first gain and outputs the second output signal; and
a second amplification circuit section that generates the first output signal by inverting-amplifying the second output signal with a second gain with a value of 1, and outputs the first output signal.

13. The angular velocity sensor according to claim 11, further comprising a high pass filter provided at a front stage of the first amplification circuit section to remove drift components from the detection signal.

14. The angular velocity sensor according to claim 1, further comprising a gain variable circuit capable of variably setting the first gain.

15. An amplification circuit of an angular velocity signal, comprising an amplification circuit section that generates both a first output signal by non-inverting amplifying a detection signal corresponding to an angular velocity with a first gain and a second output signal by inverting-amplifying the detection signal with the first gain, and outputs the first output signal and the second output signal in order to obtain an angular velocity signal by calculating a difference between the first output signal and the second output signal.

16. An electronic apparatus comprising:
a casing;
a sensor device that generates a detection signal corresponding to an angular velocity acting on the casing;
an amplification circuit that generates both a first output signal by non-inverting amplifying the detection signal with a first gain and a second output signal by inverting-amplifying the detection signal with the first gain, and outputs the first output signal and the second output signal; and
a signal processing circuit that calculates a difference between the first output signal and the second output signal to generate an angular velocity signal.

17. The electronic apparatus according to claim 16, further comprising:
an image capturing unit received in the casing to capture an object image; and
a correction mechanism that corrects a shake of the object image based on the angular velocity signal generated by the signal processing circuit.

18. A shake correction apparatus comprising:
an image capturing unit that captures an object image;
a sensor device that generates a detection signal corresponding to an angular velocity;
an amplification circuit that generates both a first output signal by non-inverting amplifying the detection signal with a first gain and a second output signal by inverting-amplifying the detection signal with the first gain, and outputs the first output signal and the second output signal;
a signal processing circuit that calculates a difference between the first output signal and the second output signal to generate an angular velocity signal; and
a correction mechanism that corrects a shake of the object image based on the angular velocity signal generated by the signal processing circuit.

19. An amplification method of an angular velocity signal, comprising the steps of:
generating a detection signal corresponding to an angular velocity;
generating both a first output signal by non-inverting amplifying the detection signal with a first gain and a second output signal by inverting-amplifying the detection signal with the first gain; and
outputting the first output signal and the second output signal in order to obtain an angular velocity signal by calculating a difference between the first output signal and the second output signal.

20. A shake correction method comprising the steps of:
generating a detection signal corresponding to an angular velocity;
generating both a first output signal by non-inverting amplifying the detection signal with a first gain and a second output signal by inverting-amplifying the detection signal with the first gain;
outputting the first output signal and the second output signal;
calculating a difference between the first output signal and the second output signal to generate an angular velocity signal; and
correcting a shake of an object image based on the generated angular velocity signal.
